(19) United States
(12) Patent Application Publication
(10) Pub. No.: US 2026/0262380 A1
(43) Pub. Date: Sep. 3, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Wenhui GAO, Beijing (CN); Miao WANG, Beijing (CN); Cong LIU, Beijing (CN); Dan CAO, Beijing (CN); Binyan WANG, Beijing (CN); Yonglin GUO, Beijing (CN); Gukhwan SONG, Beijing (CN); Zhiliang JIANG, Beijing (CN); Lang LIU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/994,664

(22) PCT Filed: Apr. 17, 2024
(86) PCT No.: PCT/CN2024/088171

§ 371 Date: Jan. 15, 2025

(30) Foreign Application Priority Data
May 30, 2023 (CN) 202310627614.1

(51) Int. Cl. H10K 59/121; G09G 3/3225; H10K 59/122

(52) U.S. Cl. CPC H10K 59/1213; G09G 3/3225; H10K 59/1216; H10K 59/122; G09G 2300/0426; G09G 2300/0819; G09G 2300/0852; G09G 2300/0861; G09G 2310/08; G09G 2320/0233; G09G 2320/0247; G09G 2320/045; G09G 2330/02

(57) ABSTRACT

A display substrate and a display device. A first initialization signal transmission layer in the display substrate includes a plurality of first initialization branches, and the first initialization branch includes a first branch body and a plurality of first branch extension member. A subpixel driving circuit includes a driving transistor and an auxiliary structure, the auxiliary structure includes a first auxiliary structure and a second auxiliary structure, and an orthogonal projection of the first auxiliary structure onto a base substrate at least partially overlaps an orthogonal projection of the second auxiliary structure onto the bae substrate. At least one first branch extension member in the plurality of first branch extension member is coupled to the first auxiliary structure in a corresponding subpixel driving circuit, and the second auxiliary structure is coupled to a gate electrode of a driving transistor in a corresponding subpixel driving circuit.

### CROSS-REFERENCE TO RELATED APPLICATION

This application claims a priority of the Chinese patent application No. 202310627614.1 filed on May 30, 2023, which is incorporated herein by reference in its entirety,

### TECHNICAL FIELD

The present disclosure relates to the field of display technology, in particular to a display substrate and a display device.

### BACKGROUND

In the market, a display device for a smart terminal is highly demanded and expected, and an average daily use time and an average daily use frequency of the smart terminal become higher and higher. Hence, it is more and more important for a display product to display an image at a low frequency so as to reduce the power consumption. A high-resolution display element is expected to be provided in a case of low-frequency and low-power-consumption display, but display uniformity of a current display product is poor in a case of low-grayscale display.

### SUMMARY

An object of the present disclosure is to provide a display substrate and a display device, so as to solve the above-mentioned problem.

In order to achieve the above object, the present disclosure provides the following technical solutions.

In one aspect, the present disclosure provides in some embodiments a display substrate, including a base substrate and a plurality of subpixels arranged on the base substrate. Each of the subpixels includes a subpixel driving circuit, a plurality of subpixel driving circuits included in the plurality of subpixels includes a plurality of subpixel driving circuit columns arranged in a first direction, each of the subpixel driving circuit columns includes a plurality of subpixel driving circuits arranged in a second direction, and the first direction intersects the second direction. The display substrate further includes a first initialization signal transmission layer including a plurality of first initialization branches, each of the first initialization branches includes a first branch body and a plurality of first branch extension members, the first branch body includes at least a portion extending in the second direction, and each of the first branch extension members includes at least a portion extending in the first direction. The subpixel driving circuit includes a driving transistor and an auxiliary structure, the auxiliary structure includes a first auxiliary structure and a second auxiliary structure, an orthogonal projection of the first auxiliary structure onto the base substrate at least partially overlaps with an orthogonal projection of the second auxiliary structure onto the base substrate, at least one first branch extension member in the plurality of first branch extension members is coupled to the first auxiliary structure in a corresponding subpixel driving circuit, and the second auxiliary structure is coupled to a gate electrode of the driving transistor of a corresponding subpixel driving circuit.

In a possible embodiment of the present disclosure, the first branch extension member includes a first sub-extension member and a second sub-extension member, the first sub-extension member is arranged at a first side of the first branch body, the first sub-extension member is coupled to the first auxiliary structure of a corresponding subpixel driving circuit at the first side of the first branch body, the second sub-extension member is arranged at a second side of the first branch body, the second sub-extension member is coupled to the first auxiliary structure of a corresponding subpixel driving circuit at the second side of the first branch body, and the first side and the second side are different sides of the first branch body.

In a possible embodiment of the present disclosure, the display substrate includes an active layer, and the first auxiliary structure is arranged at a same layer, and made of a same material, as the active layer.

In a possible embodiment of the present disclosure, the first auxiliary structure includes a first sub-portion and at least two second sub-portions, the at least two second sub-English portions are coupled to the first sub-portion, the first sub-portion is coupled to a corresponding first sub-extension member or second sub-extension member, and an orthogonal projection of the second auxiliary structure onto the base substrate at least partially overlaps with an orthogonal projection of the second sub-portion onto the base substrate.

In a possible embodiment of the present disclosure, the subpixel driving circuit further includes storage capacitors, second plates of the storage capacitors proximate to each other in the first direction are coupled to each other via a conductive member, and an orthogonal projection of the first sub-extension member onto the base substrate at least partially overlaps with an orthogonal projection of the conductive member onto the base substrate.

In a possible embodiment of the present disclosure, the second auxiliary structure and a gate electrode of the driving transistor form an integral piece, and an orthogonal projection of the second auxiliary structure onto the base substrate at least partially overlaps with the orthogonal projection of the conductive member onto the base substrate.

In a possible embodiment of the present disclosure, the display substrate further includes a second gate metal layer, the first auxiliary structure is arranged at a same layer, and made of a same material, as the second gate metal layer, and a capacitor structure is formed between the first auxiliary structure and the second auxiliary structure.

In a possible embodiment of the present disclosure, the display substrate further includes a first source/drain metal layer, and the first initialization signal transmission layer is arranged at a same layer, and made of a same material, as the first source/drain metal layer.

In a possible embodiment of the present disclosure, the display substrate further includes a second initialization signal transmission layer including a plurality of second initialization branches and a plurality of third initialization branches, the plurality of second initialization branches is arranged in the first direction, the plurality of third initialization branches is arranged in the second direction, and the third initialization branch is coupled to the plurality of second initialization branches.

In a possible embodiment of the present disclosure, the display substrate further includes a second gate metal layer and a first source/drain metal layer, the second initialization branch is arranged at a same layer, and made of a same material, as the first source/drain metal layer, and the third initialization branch is arranged at a same layer, and made of a same material, as the second gate metal layer.

In a possible embodiment of the present disclosure, the subpixel includes a light-emitting element, the subpixel driving circuit further includes a second resetting transistor, a second electrode of the second resetting transistor is coupled to the light-emitting element, and the third initialization branch is coupled to a first electrode of the second resetting transistor included in a corresponding subpixel driving circuit.

In a possible embodiment of the present disclosure, the second initialization branch includes a second branch body and a plurality of second branch extension members, the second branch body extends in the second direction, each of the second branch extension members protrudes from the second branch body in the first direction, the second branch extension member is coupled to a corresponding third initialization branch, and an orthogonal projection of the second branch extension member onto the base substrate at least partially overlaps with an orthogonal projection of the third initialization branch onto the base substrate.

In a possible embodiment of the present disclosure, the second branch extension member includes a third sub-extension member and a fourth sub-extension member, the third sub-extension member includes at least a portion extending in the first direction, and the fourth sub-extension member includes at least a portion extending in the second direction. An orthogonal projection of the third sub-extension member onto the base substrate is located within the orthogonal projection of the third initialization branch onto the base substrate, and a boundary of the orthogonal projection of the third sub-extension member onto the base substrate at least partially overlaps with a boundary of the orthogonal projection of the third initialization branch onto the base substrate.

In a possible embodiment of the present disclosure, the display substrate further includes a third initialization signal transmission layer including a plurality of fourth initialization branches, and each of the fourth initialization branches includes at least a portion extending in the first direction. The subpixel driving circuity further includes a first resetting transistor, a second electrode of the first resetting transistor is coupled to the gate electrode of the driving transistor, and the fourth initialization branch is coupled to a first electrode of the first resetting transistor of the subpixel driving circuits in a corresponding subpixel driving circuit row.

In a possible embodiment of the present disclosure, the first resetting transistor includes a first resetting active layer, the first resetting active layer includes two first channel portions and a first conductor portion, the first conductor portion is coupled to the two first channel portions, and the orthogonal projection of the third initialization branch onto the base substrate at least partially overlaps with an orthogonal projection of the first conductor portion onto the base substrate.

In a possible embodiment of the present disclosure, the subpixel driving circuit further includes a compensation transistor, a first electrode of the compensation transistor is coupled to a second electrode of the driving transistor, a second electrode of the compensation transistor is coupled to the gate electrode of the driving transistor, the compensation transistor includes a compensation active layer, the compensation active layer includes two compensation channel portions and one compensation conductor portion, the compensation conductor portion is coupled to the two compensation channel portions, and an orthogonal projection of the fourth initialization branch onto the base substrate at least partially overlaps with an orthogonal projection of the compensation conductor portion onto the base substrate.

In a possible embodiment of the present disclosure, an orthogonal projection of the fourth initialization branch onto the base substrate at least partially overlaps with an orthogonal projection of the second sub-extension member onto the base substrate.

In a possible embodiment of the present disclosure, the display substrate further includes a data line, and an orthogonal projection of the first branch body onto the base substrate at least partially overlaps with an orthogonal projection of the data line onto the base substrate, or an orthogonal projection of the second initialization branch onto the base substrate at least partially overlaps with the orthogonal projection of the data line onto the base substrate.

In a possible embodiment of the present disclosure, the third initialization signal transmission layer further includes a plurality of fifth initialization branches, each of the fifth initialization branches includes at least a portion extending in the second direction, and the fifth initialization branch is coupled to the plurality of fourth initialization branches. In the first direction, orthogonal projections of a first branch bodies onto the base substrate, orthogonal projections of b second branch bodies onto the base substrate and orthogonal projections of c fifth initialization branches onto the base substrate are arranged alternately, where a is an integer greater than or equal to 1, b is an integer greater than or equal to 1, and c is an integer greater than or equal to 1.

In a possible embodiment of the present disclosure, the display substrate further includes a power source layer, the power source layer includes a first power source sub-layer, the first power source sub-layer includes a first power source sub-member and a second power source sub-member arranged in the first direction, and a length of an orthogonal projection of the first power source sub-member onto the base substrate in the second direction is greater than a length of an orthogonal projection of the second power source sub-member onto the base substrate in the second direction.

In a possible embodiment of the present disclosure, the display substrate further includes a power source layer, the power source layer includes a first power source sub-layer, the first power source sub-layer includes a first power source sub-member and a second power source sub-member arranged in the first direction, and an orthogonal projection of the second power source sub-member onto the base substrate does not overlap with an orthogonal projection of the first branch extension member onto the base substrate.

In a possible embodiment of the present disclosure, the power source layer further includes a second power source sub-layer arranged at a side of the first power source sub-layer distal to the base substrate, the second power source sub-layer includes a plurality of third power source sub-members arranged in the first direction, and an orthogonal projection of the third power source sub-member onto the base substrate covers the orthogonal projection of the first power source sub-member onto the base substrate, and/or the orthogonal projection of the third power source sub-member onto the base substrate covers the orthogonal projection of the second power source sub-member onto the base substrate. At least one of the first power source sub-member or the second power source sub-member is coupled to the third power source sub-member.

In a possible embodiment of the present disclosure, the display substrate further includes a pixel definition layer defining a pixel aperture region of the subpixel, the third power source sub-member is coupled to a corresponding first power source sub-member via a first adaption hole, the third power source sub-member is coupled to a corresponding second power source sub-member via a second adaption hole, an orthogonal projection of the first adaption hole onto the base substrate does not overlap with an orthogonal projection of the pixel aperture region onto the base substrate, and an orthogonal projection of the second adaption hole onto the base substrate does not overlap with the orthogonal projection of the pixel aperture region onto the base substrate.

In a possible embodiment of the present disclosure, the subpixel includes a green subpixel, and the orthogonal projection of the first adaption hole onto the base substrate is located at a periphery of the orthogonal projection of the pixel aperture region of the green subpixel onto the base substrate, or the orthogonal projection of the second adaption hole onto the base substrate is located at the periphery of the orthogonal projection of the pixel aperture region of the green subpixel onto the base substrate.

In a possible embodiment of the present disclosure, the third power source sub-member includes a power source body and a power source extension portion, the power source body includes at least a portion extending in the second direction, and the power source extension portion protrudes from the power source body in the first direction. At least a part of the subpixels include a conductive connection member, and the conductive connection member is coupled to the subpixel driving circuit and an anode pattern of a light-emitting element in the subpixel. An orthogonal projection of the anode pattern in at least a part of the subpixels of the display substrate onto the base substrate at least partially overlaps with an orthogonal projection of the conductive connection member onto the base substrate and at least partially overlaps with an orthogonal projection of the power source extension portion onto the base substrate, the conductive connection member is arranged at a same layer, and made of a same material, as the power source extension portion, and the conductive connection member is arranged opposite to the power source extension portion in the first direction.

In a possible embodiment of the present disclosure, the display substrate further includes a plurality of first scanning lines, the subpixel driving circuit further includes a data write-in transistor and a second resetting transistor, and gate electrodes of the data write-in transistors and gate electrodes of the second resetting transistors in a same subpixel driving circuit row are coupled to a same first scanning line.

In a possible embodiment of the present disclosure, the subpixel driving circuit further includes a data write-in transistor, and an orthogonal projection of the data write-in transistor onto the base substrate and an orthogonal projection of the auxiliary structure onto the base substrate are arranged at a same side of an orthogonal projection of the gate electrode of the driving transistor onto the base substrate.

In a possible embodiment of the present disclosure, the subpixel diving circuit further includes a data write-in transistor and a power source control transistor, an orthogonal projection of the data write-in transistor onto the base substrate is arranged at a third side of an orthogonal projection of a first electrode of the driving transistor onto the base substrate, an orthogonal projection of the power source control transistor onto the base substrate is arranged at the third side of the orthogonal projection of the first electrode of the driving transistor onto the base substrate, an orthogonal projection of the auxiliary structure onto the base substrate is arranged at a fourth side of the orthogonal projection of the first electrode of the driving transistor onto the base substrate, and the third side is opposite to the fourth side in the second direction.

In a possible embodiment of the present disclosure, the subpixel driving circuit further includes a compensation transistor and a light-emission control transistor, an orthogonal projection of a first electrode of the compensation transistor onto the base substrate at least partially overlaps with an orthogonal projection of the first branch body onto the base substrate, and an orthogonal projection of a first electrode of the light-emission control transistor onto the base substrate at least partially overlaps with the orthogonal projection of the first branch body onto the base substrate.

In a possible embodiment of the present disclosure, the subpixel driving circuit further includes a storage capacitor, an orthogonal projection of the first branch body onto the base substrate at least partially overlaps with an orthogonal projection of a second plate of the storage capacitor onto the base substrate, and/or an orthogonal projection of the second initialization branch onto the base substrate at least partially overlaps with the orthogonal projection of the second plate of the storage capacitor onto the base substrate.

In a second aspect, the present disclosure provides in some embodiments a display device, including the above-mentioned display substrate.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a circuit diagram of a subpixel driving circuit according to one embodiment of the present disclosure;

FIG. 2 is a driving sequence diagram of the subpixel driving circuit according to one embodiment of the present disclosure;

FIG. 3 is a sectional view of a display substrate according to one embodiment of the present disclosure;

FIG. 4 is a schematic view showing the layout of an active layer in two subpixel driving circuits according to one embodiment of the present disclosure;

FIG. 5 is a schematic view showing the layout of a first gate metal layer added on the basis of FIG. 4;

FIG. 6 is another schematic view showing the layout of the active layer in the two subpixel driving circuits according to one embodiment of the present disclosure;

FIG. 7 is a schematic view showing the layout of the first gate metal layer added on the basis of FIG. 6;

FIG. 8 is a schematic view showing the layout of the active layer to a first source/drain metal layer in two subpixel driving circuits according to one embodiment of the present disclosure;

FIG. 9 is a schematic view showing the layout of the active layer the first gate metal layer and a second gate metal layer in FIG. 8;

FIG. 10 is a schematic view showing the layout of the active layer in FIG. 8;

FIG. 11 is a schematic view showing the layout of the first gate metal layer in FIG. 8;

FIG. 12 is a schematic view showing the layout of the second gate metal layer in FIG. 8;

FIG. 13 is a schematic view showing the layout of the first source/drain metal layer in FIG. 8;

FIG. 14 is a schematic view showing via-holes formed in an interlayer insulation layer in FIG. 8;

FIG. 15 is a schematic view showing the layout of two subpixel driving circuits according to one embodiment of the present disclosure;

FIG. 16 is a schematic view showing via-holes formed in the interlayer insulation layer in FIG. 15;

FIG. 17 is a schematic view showing the layout of the first source/drain metal layer in FIG. 15;

FIG. 18 is a schematic view showing the layout of the second gate metal layer and the first source/drain metal layer in FIG. 15;

FIG. 19 is a schematic view showing the layout of the active layer, the second gate metal layer and the first source/drain metal layer in FIG. 15;

FIG. 20 is a schematic view showing the layout of the second gate metal layer, the first source/drain metal layer and the second source/drain metal layer in FIG. 15;

FIG. 21 is another schematic view showing the layout of the two subpixel driving circuits according to one embodiment of the present disclosure;

FIG. 22 is a schematic view showing the layout of the active layer and the first gate metal layer in FIG. 21;

FIG. 23 is a schematic view showing the layout of the first gate metal layer and the second gate metal layer in FIG. 21;

FIG. 24 is a schematic view showing the layout of the second gate metal layer and the first source/drain metal layer in FIG. 21;

FIG. 25 is a schematic view showing the layout of the active layer, the second gate metal layer and the first source/drain metal layer in FIG. 21;

FIG. 26 is a schematic view showing the layout of the second gate metal layer, the first source/drain metal layer and the second source/drain metal layer in FIG. 21;

FIG. 27 is a schematic view showing the layout of a light-shielding layer in FIG. 21;

FIG. 28 is a schematic view showing the layout of the active layer in FIG. 21;

FIG. 29 is a schematic view showing the layout of the first gate metal layer in FIG. 21;

FIG. 30 is a schematic view showing the layout of the second gate metal layer in FIG. 21;

FIG. 31 is a schematic view showing the layout of via-holes formed in the interlayer insulation layer in FIG. 21;

FIG. 32 is a schematic view showing the layout of the first source/drain metal layer in FIG. 21;

FIG. 33 is a schematic view showing the layout of via-holes formed in a first planarization layer in FIG. 21;

FIG. 34 is a schematic view showing the layout of the second source/drain metal layer in FIG. 21;

FIG. 35 is a schematic view showing the layout of pixel aperture regions and adaption holes according to one embodiment of the present disclosure;

FIG. 36 is a schematic view showing the layout of the active layer, the first gate metal layer and the second gate metal layer in two subpixel driving circuits according to one embodiment of the present disclosure;

FIG. 37 is a schematic view showing the layout of the second gate metal layer and the first source/drain metal layer in two subpixel driving circuits according to one embodiment of the present disclosure;

FIG. 38 is a schematic view showing an auxiliary structure according to one embodiment of the present disclosure; and

FIG. 39 is a schematic view showing the layout of the active layer and the first source/drain metal layer in FIG. 15.

### DETAILED DESCRIPTION OF THE EMBODIMENTS

The present disclosure will be described hereinafter in conjunction with the drawings and embodiments.

The present provides in some embodiments a display substrate, which includes a base substrate and a plurality of subpixels arranged on the base substrate. Each of the subpixels includes a subpixel driving circuit, a plurality of subpixel driving circuits included in the plurality of subpixels includes a plurality of subpixel driving circuit columns arranged in a first direction, each of the subpixel driving circuit columns includes a plurality of subpixel driving circuits arranged in a second direction, and the first direction intersects the second direction.

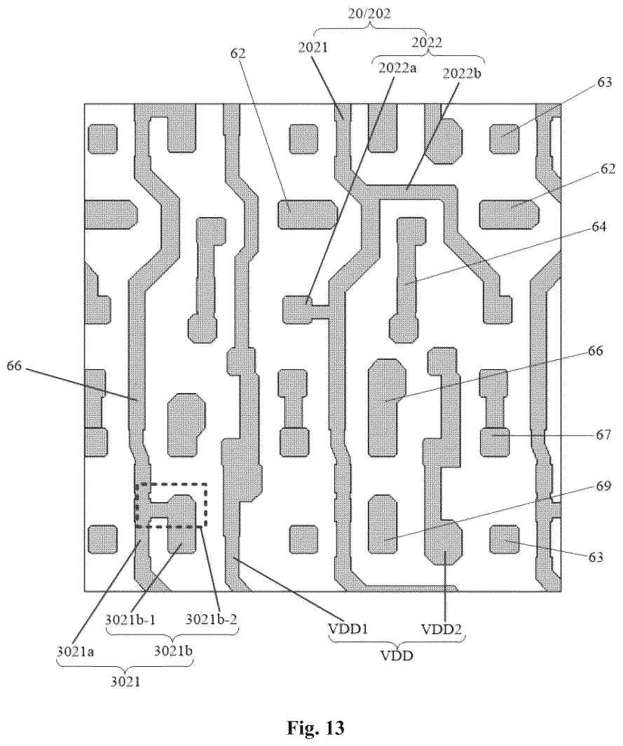

As shown in FIGS. 13, 17 and 32, the display substrate further includes a first initialization signal transmission layer 20 including a plurality of first initialization branches 202, the first initialization branch 202 includes a first branch body 2021 and a plurality of first branch extension members 2022, the first branch body 2021 includes at least a portion extending in the second direction, and the first branch extension member 2022 includes at least a portion extending in the first direction.

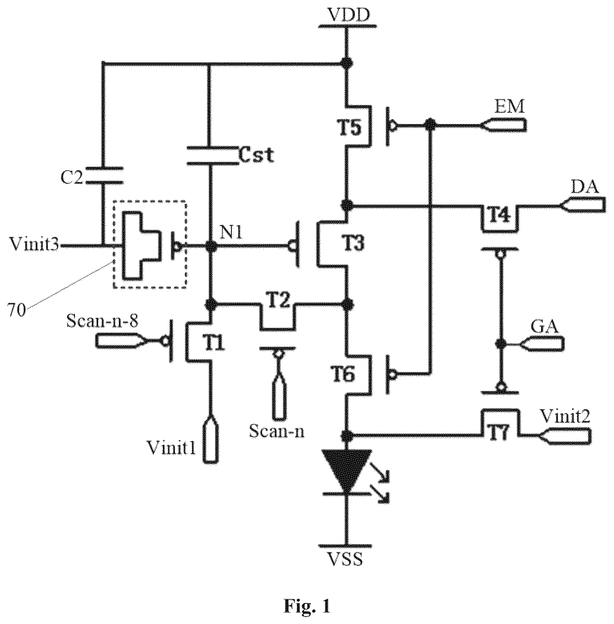

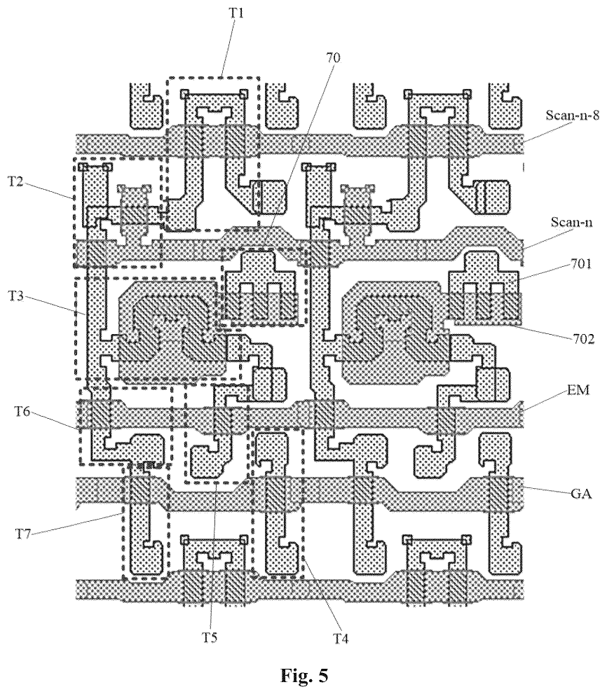

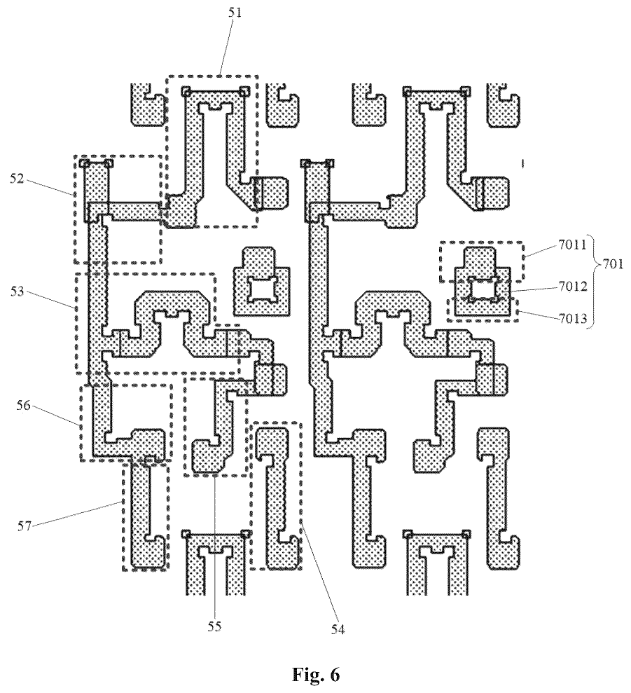

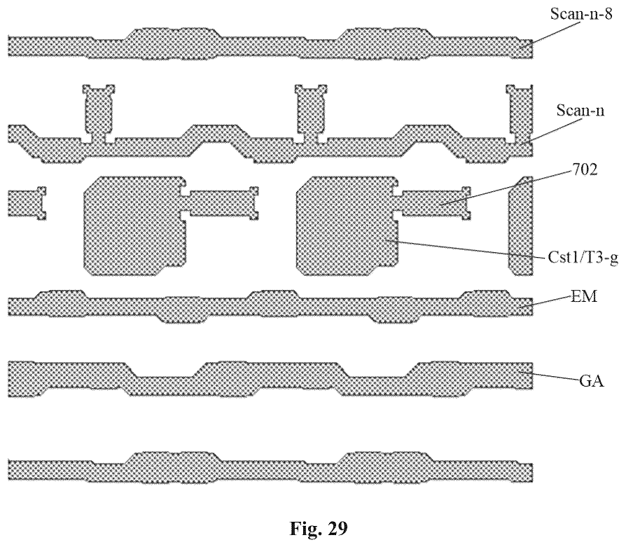

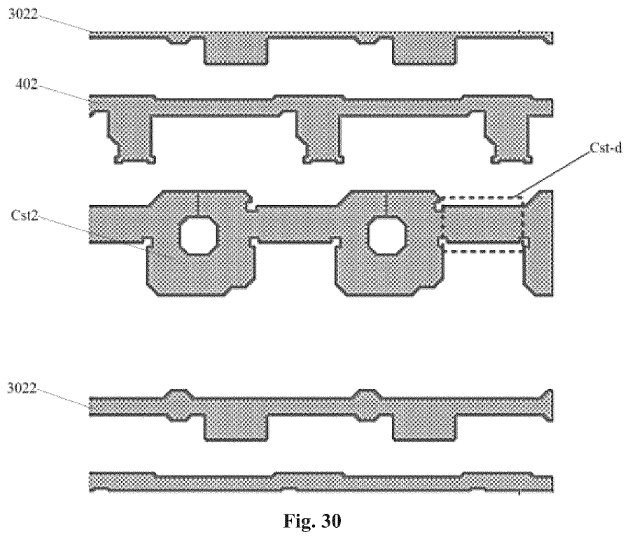

As shown in FIGS. 1, 5, 7, 8, 15, 22 and 29, the subpixel driving circuit includes a driving transistor and an auxiliary structure 70, the auxiliary structure includes a first auxiliary structure 701 and a second auxiliary structure 702, an orthogonal projection of the first auxiliary structure 701 onto the base substrate at least partially overlaps with an orthogonal projection of the second auxiliary structure 702 onto the base substrate, at least one first branch extension member 2022 in the plurality of first branch extension members 2022 is coupled to the first auxiliary structure 701 in a corresponding subpixel driving circuit, and the second auxiliary structure 702 is coupled to a gate electrode of the driving transistor of a corresponding subpixel driving circuit.

For example, the display substrate includes a plurality of subpixels, and the plurality of subpixel driving circuits included in the plurality of subpixels is arranged in an array form. The plurality of subpixel driving circuits includes a plurality of subpixel driving circuit rows and a plurality of subpixel driving circuit columns. The plurality of subpixel driving circuit rows is arranged in the second direction, and the subpixel driving circuit row includes a plurality of subpixel driving circuits arranged in the first direction. The plurality of subpixel driving circuit columns is arranged in the first direction, and the subpixel driving circuit column includes a plurality of subpixel driving circuits arranged in the second direction. For example, the first direction intersects the second direction. For example, the first direction includes a transverse direction, and the second direction includes a longitudinal direction.

For example, the subpixel includes a subpixel driving circuit and a light-emitting element. The subpixel driving circuit is coupled to an anode of the light-emitting element, and configured to provide a driving signal to the light-emitting element, so as to drive the light-emitting element to emit light.

For example, the plurality of subpixel driving circuit columns includes a plurality of column units, and each of the column units includes at least two adjacent subpixel driving circuit columns. The plurality of subpixel driving circuit columns includes a plurality of column units, the plurality of column units is arranged in the first direction, and the column unit includes at least one subpixel driving circuit column. For example, the column unit includes at least two adjacent subpixel driving circuit columns. For example, the plurality of first initialization branches 202 corresponds to the plurality of column units respectively. The first initialization branch 202 is located in a layout region where the corresponding column unit is located. It should be appreciated that, the layout region of the column unit refers to a layout region occupied by all subpixel driving circuits in the column unit. A layout region occupied by the subpixel driving circuit is a region for accommodating the subpixel driving circuit. For example, the region is, but not limited to, a rectangular region. Based on the above arrangement, the first auxiliary structure in the column unit receives an initialization signal via a corresponding first initialization branch 202, so it is able to reduce the quantity of first initialization branches 202, thereby to reduce a layout difficulty of the first initialization signal transmission layer 20 in a limited layout space, and increase a resolution of the display substrate.

For example, the first initialization signal transmission layer 20 is configured to transmit a third initialization signal Vinit3.

For example, the quantity of first branch bodies 2021 is smaller than the quantity of subpixel driving circuit columns.

For example, the first branch extension member 2022 is coupled to the first auxiliary structure in the corresponding subpixel driving circuit and the first branch body 2021.

For example, the first auxiliary structure 701 is configured to receive the third initialization signal Vinit3.

For example, the second auxiliary structure 702 and the gate electrode of the driving transistor form an integral piece.

For example, the first branch body 2021 is coupled to the first auxiliary structure 701 in a corresponding column unit via the plurality of first branch extension members 2022.

Based on the specific structure of the display substrate in the embodiments of the present disclosure, the first auxiliary structure receives the initialization signal via the corresponding first initialization branch 202. As a result, it is able to not only ensure that the first auxiliary structure in the display substrate receives the initialization signal but also reduce the quantity of first initialization branches 202, thereby to reduce a layout difficulty of the first initialization signal transmission layer 20 in a limited layout space, and increase the resolution of the display substrate.

In addition, the first initialization branch 202 includes the first branch body 2021 and the plurality of first branch extension members 2022, and at least one first branch extension member in the plurality of first branch extension members 2022 is coupled to the first auxiliary structure 701 in the corresponding subpixel driving circuit. In this way, it is able to effectively reduce a length of the first initialization branch 202, and reduce a loading of the first initialization branch 202, thereby to ensure a uniform voltage of the initialization signal received by the subpixel driving circuits at different positions, ensure the display uniformity of a display product in a case of low-grayscale display, and prevent the occurrence of mura.

Furthermore, in the display substrate according to the embodiments of the present disclosure, the auxiliary structure 70 includes the first auxiliary structure 701 and the second auxiliary structure 702 arranged opposite to each other, the first auxiliary structure 701 is coupled to the corresponding first branch extension member 2022, and the second auxiliary structure 702 is coupled to the gate electrode of the driving transistor in the corresponding subpixel driving circuit. In a display process of the display substrate, a voltage of the third initialization signal Vinit3 is adjusted, so as to change an intensity of an electric field between a channel of the driving transistor and the first auxiliary structure 701, so as to prevent the distribution of defect-state particles at an interface of the channel of the driving transistor from being adversely affected by the electric field, thereby to adjust a hysteresis state of the driving transistor. In addition, the second auxiliary structure 702 is coupled to the gate electrode of the driving transistor, and the second auxiliary structure 702 and the first auxiliary structure 701 form a variable capacitor. In a case of low-frequency writing and within a skip frame, the voltage of the third initialization signal Vinit3 is adjusted, so as to adjust and compensate for a capacitance of a storage capacitor Cst at a node N1 as well as a voltage at the node N1, thereby to reduce an influence of a leakage current Ioff on the voltage at the node N1 in a case of low-frequency display. It is able for the display substrate in the embodiments of the present disclosure to remarkably increase a voltage holding rate of the node N1 within one frame at a frequency of 40 Hz, 30 Hz or even 24 Hz, thereby to remarkably improve a flicker effect.

In some embodiments of the present disclosure, all the subpixel driving circuits in the column unit include a plurality of row units arranged in the second direction, each of the row units includes at least two subpixel driving circuits arranged in the first direction, and the first branch extension member 2022 is coupled to the first auxiliary structures 701 included in the subpixel driving circuits in a corresponding row unit.

For example, the plurality of row units corresponds to the plurality of first branch extension members 2022 included in one first initialization branch 202.

Based on the above arrangement, it is able to not only ensure that the first auxiliary structures 701 in the display substrate receive the initialization signal, but also effectively reduce the layout difficulty of the first initialization signal transmission layer 20 in a limited layout space.

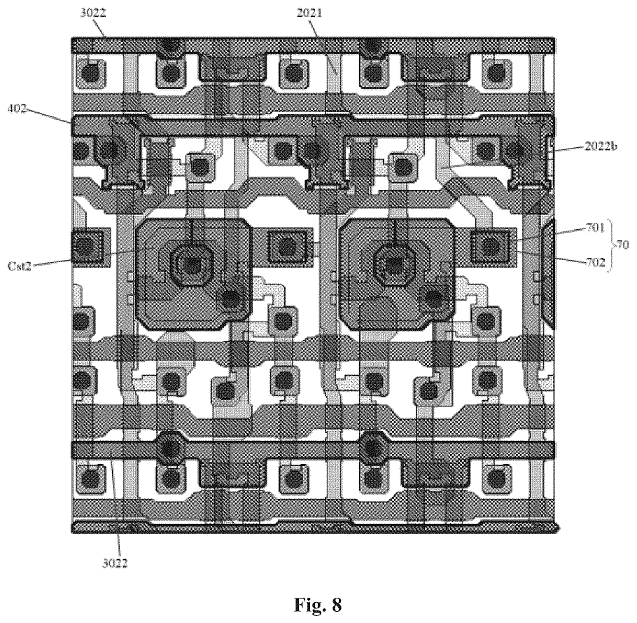

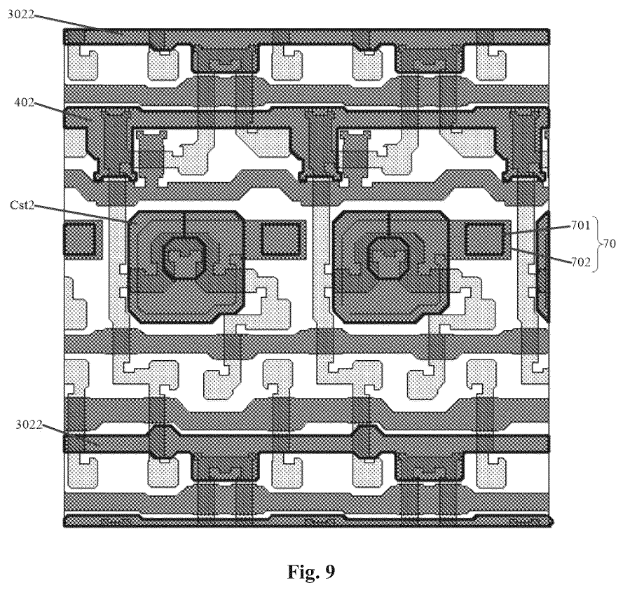

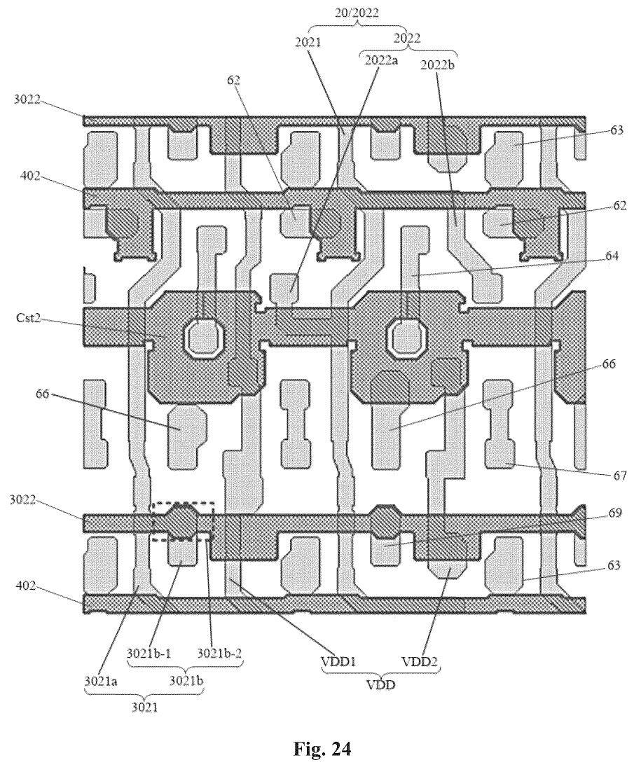

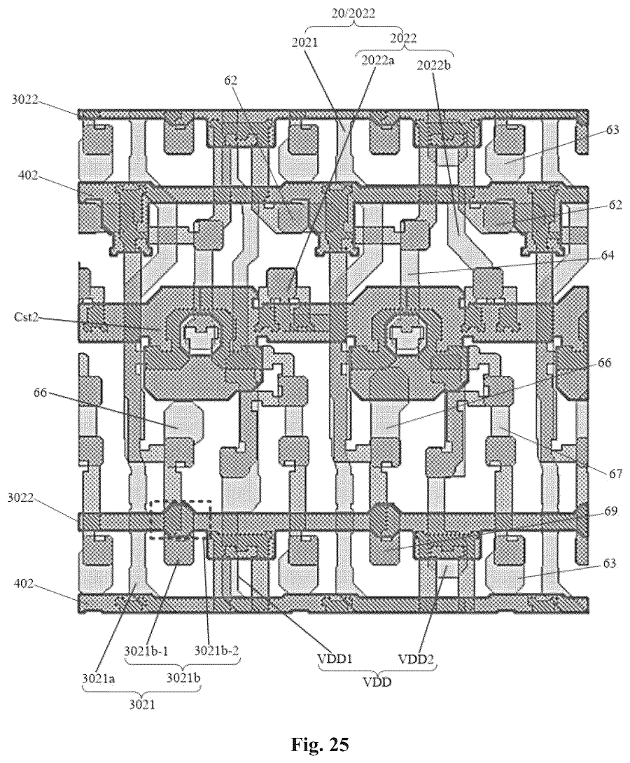

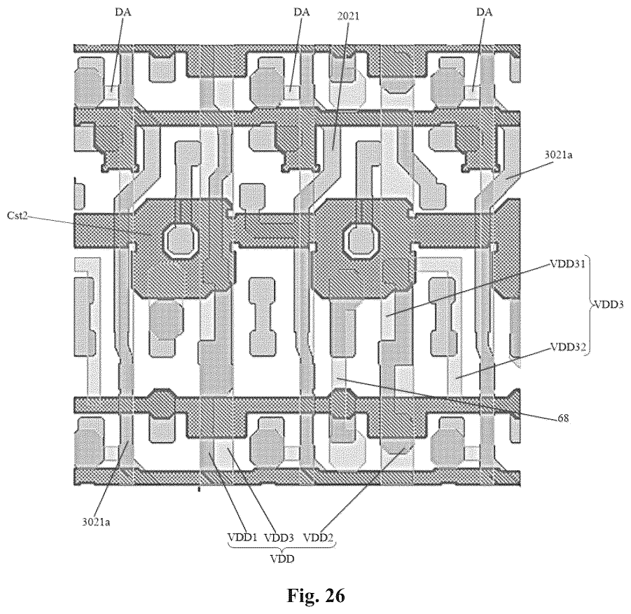

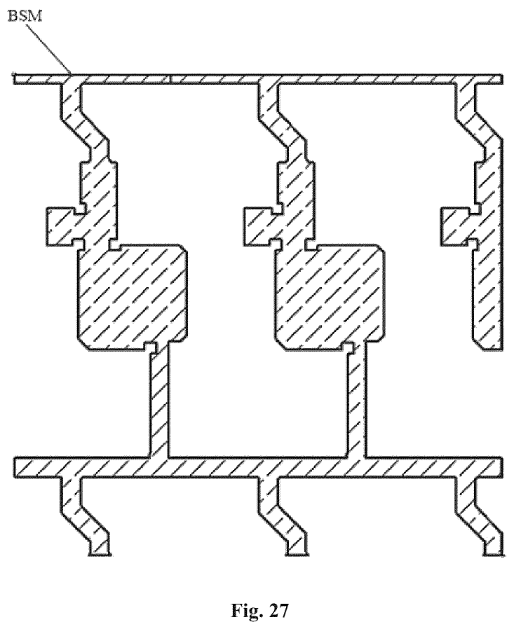

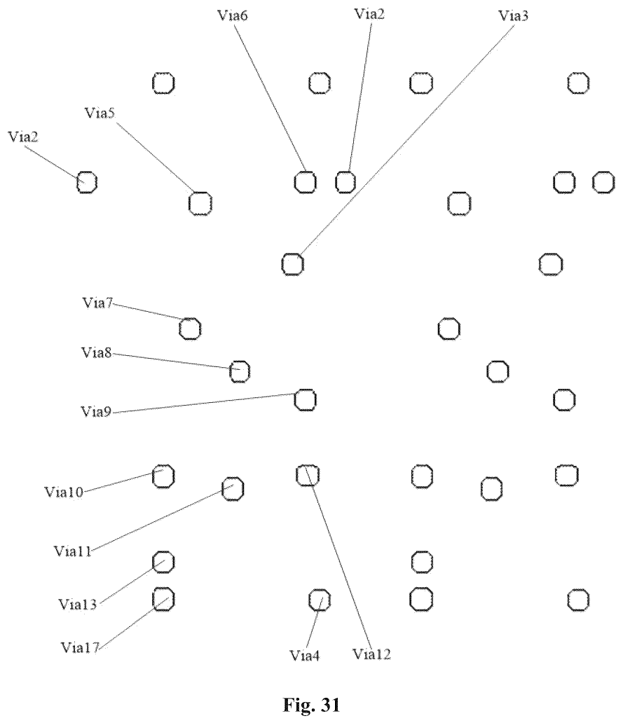

As shown in FIGS. 8, 9, 13, 15, 17, 19 and 21 to 32, in some embodiments of the present disclosure, the first branch extension member 2022 includes a first sub-extension member 2022a and a second sub-extension member 2022b, the first sub-extension member 2022a is arranged at a first side of the first branch body 2021, the first sub-extension member 2022a is coupled to the first auxiliary structure 701 of a corresponding subpixel driving circuit at the first side of the first branch body 2021, the second sub-extension member 2022b is arranged at a second side of the first branch body 2021, the second sub-extension member 2022a is coupled to the first auxiliary structure 701 of a corresponding subpixel driving circuit at the second side of the first branch body 2021, and the first side and the second side are different sides of the first branch body.

For example, the first side is opposite to the second side in the first direction.

As shown in FIGS. 8, 9, 13, 15, 17, 19 and 21 to 32, in some embodiments of the present disclosure, the first branch extension member 2022 includes the first sub-extension member 2022a and the second sub-extension member 2022b. The first sub-extension member 2022a is arranged at the first side of the first branch body 2021, and the first sub-extension member 2022a is coupled to the first auxiliary structures 701 in the corresponding row unit at the first side of the first branch body 2021. The second sub-extension member 2022b is arranged at the second side of the first branch body 2021, the second sub-extension member 2022b is coupled to the fist auxiliary structures 701 in the corresponding row unit at the second side of the first branch body 2021, and the first side is opposite to the second side in the first direction.

For example, at least a part of an orthogonal projection of the first branch body 2021 onto the base substrate is arranged between an orthogonal projection of the first sub-extension member 2022a onto the base substrate and an orthogonal projection of the second sub-extension member 2022b onto the base substrate.

For example, the orthogonal projection of the first branch body 2021 onto the base substrate is arranged between an orthogonal projection of a subpixel driving circuit coupled to the first sub-extension member 2022a onto the base substrate and an orthogonal projection of a subpixel driving circuit coupled to the second sub-extension member 2022b onto the base substrate.

For example, the orthogonal projection of the first branch body 2021 onto the base substrate at least partially overlaps with orthogonal projections of a column of subpixel driving circuits in a corresponding column unit onto the base substrate.

For example, a first end of the first sub-extension member 2022a is coupled to the first branch body 2021, and a first end of the second sub-extension member 2022b is coupled to the first branch body 2021. The first end of the first sub-extension member 2022a is staggered with the first end of the second sub-extension member 2022b in the second direction.

Based on the above arrangement, the first branch extension member 2022 includes the first sub-extension member 2022a and the second sub-extension member 2022b, so as to reduce a length of the sub-extension member, ensure that the first auxiliary structures 701 of the subpixel driving circuits in the display substrate receive the initialization signal, effectively reduce the layout difficulty of the first branch extension member 2022 in a limited layout space, and reduce the loading of the sub-extension member.

As shown in FIGS. 8, 9, 13, 15, 17, 19 and 21 to 32, in some embodiments of the present disclosure, the column unit includes two adjacent subpixel driving circuit columns, and the row unit includes two subpixel driving circuits. The first sub-extension member 2022a is coupled to the first auxiliary structure 701 in one subpixel driving circuit, and the second sub-extension member 2022b is coupled to the first auxiliary structure 701 in the other subpixel driving circuit.

For example, two subpixel driving circuits proximate to each other in the first direction forms a minimum repeat unit.

Based on the above arrangement, it is able to effectively reduce the layout difficulty of the first initialization branch 202 in a limited space, and reduce the loading of the first initialization branch 202.

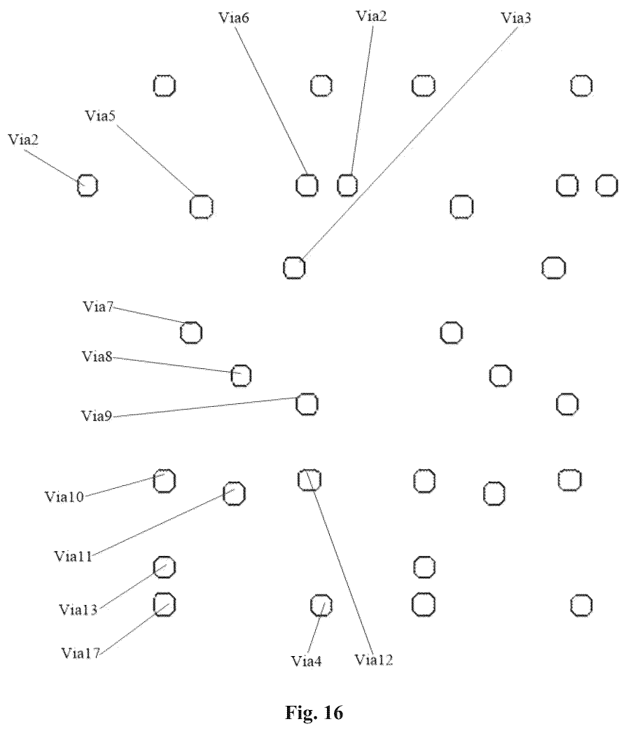

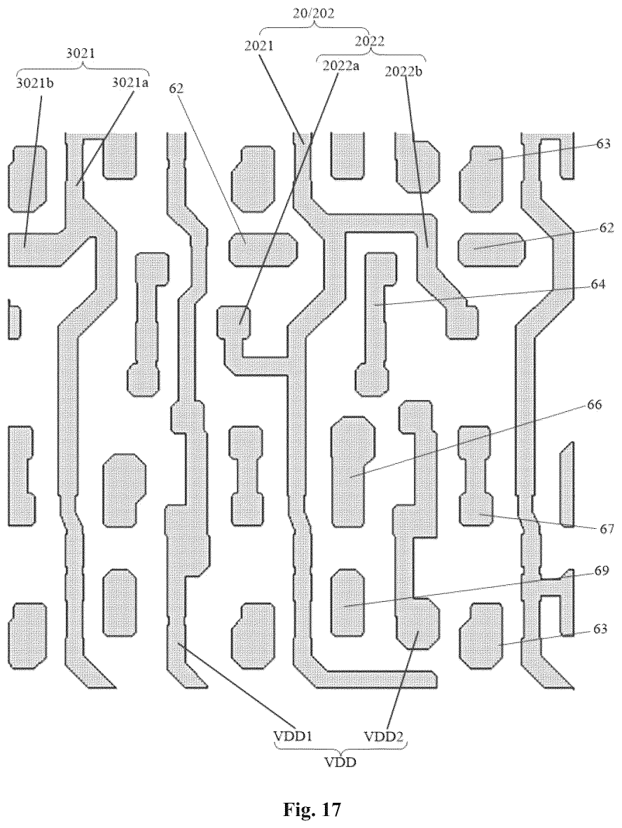

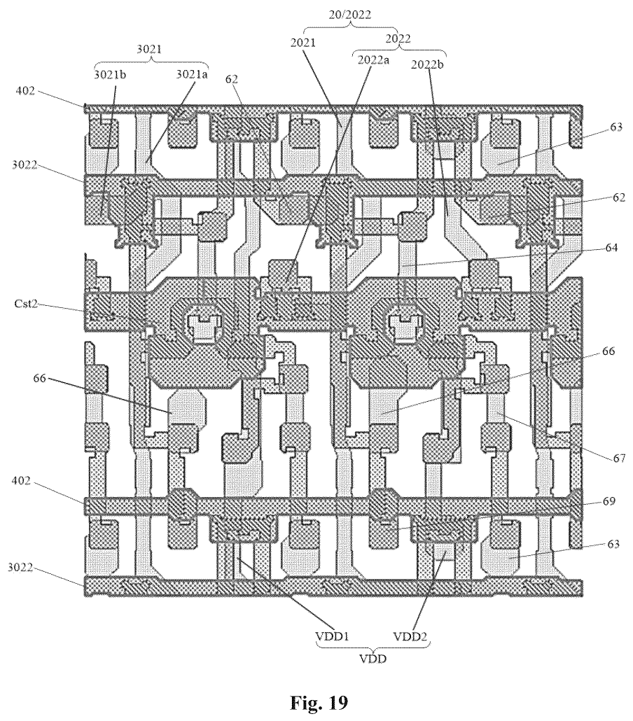

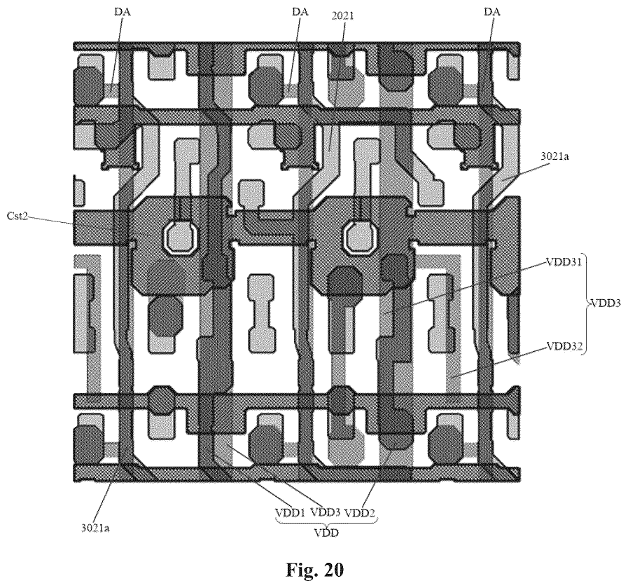

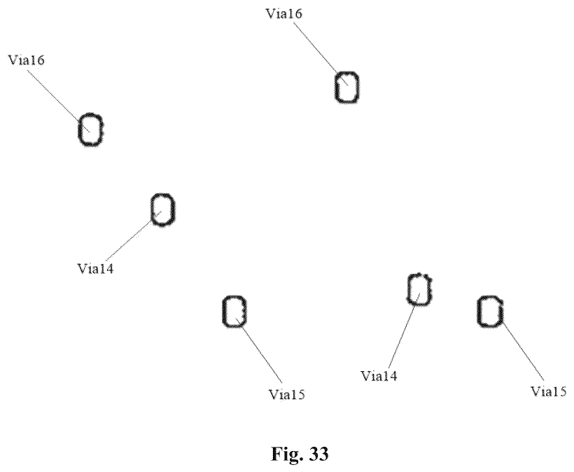

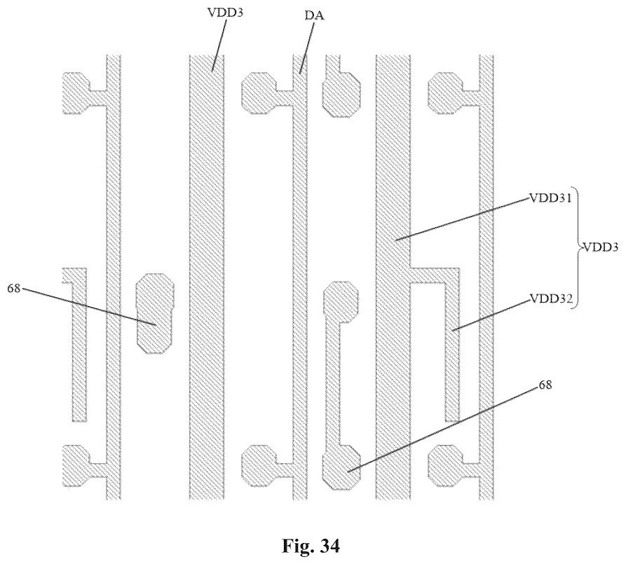

As shown in FIGS. 4 to 7 and 15 to 34, in some embodiments of the present disclosure, the display substrate includes an active layer, and the first auxiliary structure 701 is arranged at a same layer, and made of a same material, as the active layer. Based on the above arrangement, it is able to form the first auxiliary structure 701 and the active layer simultaneously through a single patterning process.

For example, the first auxiliary structure 701 includes a conductor portion and/or a semiconductor portion.

The second auxiliary structure 702 overlaps with the first auxiliary structure 701 to form a variable capacitor, so as to compensate for the voltage at the node NI within the skip frame.

As shown in FIGS. 4 to 7 and 15 to 34, in some embodiments of the present disclosure, the first auxiliary structure 701 includes a first sub-portion 7011 and at least two second sub-portions 7012, the at least two second sub-portions 7012 are coupled to the first sub-portion 7011, the first sub-portion 7011 is coupled to a corresponding first sub-extension member 2022a or second sub-extension member 2022b, and an orthogonal projection of the second auxiliary structure 702 onto the base substrate at least partially overlaps with an orthogonal projection of the second sub-portion 7012 onto the base substrate.

For example, the first auxiliary structure 701 includes two second sub-portions 7012 or three second sub-portions 7012. The first auxiliary structure 701 is of a comb-like structure.

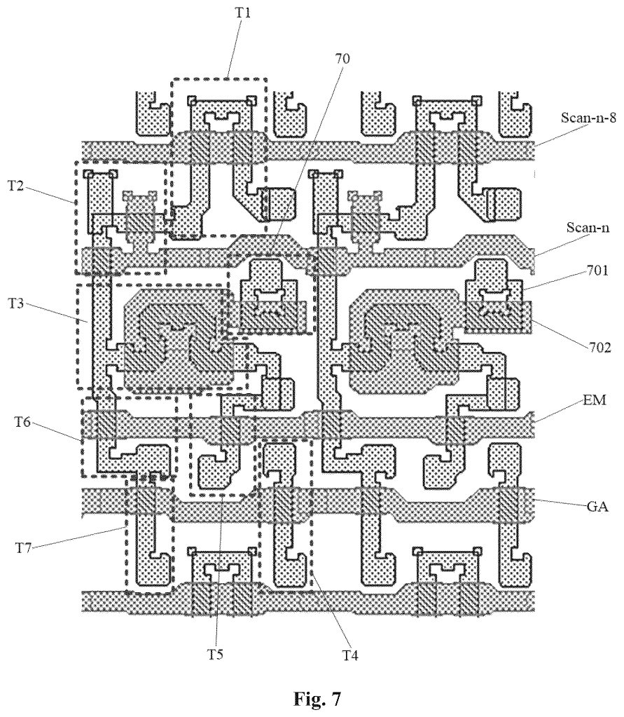

As shown in FIGS. 6 and 7, in some embodiments of the present disclosure, the first auxiliary structure 701 further includes a third sub-portion 7013, the third sub-portion 7013 is coupled to an end of the second sub-portion 7012 distal to the first sub-portion 7011, and an orthogonal projection of the third sub-portion 7013 onto the base substrate at least partially overlaps with the orthogonal projection of the second auxiliary structure 702 onto the base substrate.

For example, the third sub-portion 7013 and the second sub-portions 7012 form an integral piece.

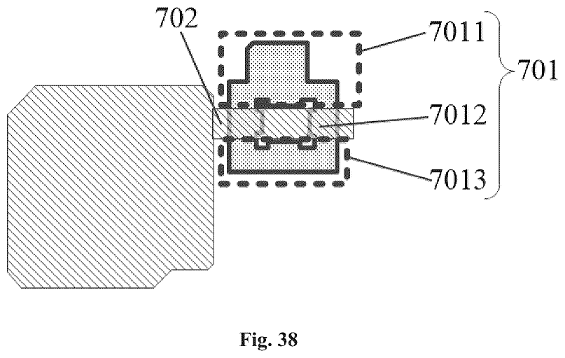

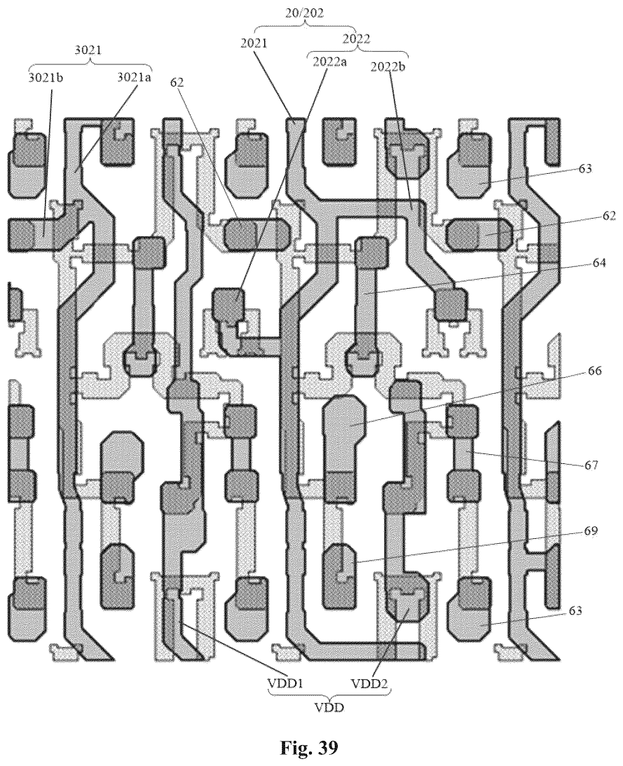

As shown in FIG. 38, the orthogonal projection of the second sub-portion 7012 onto the base substrate at least partially overlaps with the orthogonal projection of the second auxiliary structure 702 onto the base substrate.

For example, in the display substrate, a part of, or all of, the subpixel driving circuits include a compensation structure 70,

For example, a shape and an area of the third sub-portion 7013 are adjustable.

For example, an area of each of the first sub-portion 7011, the second sub-portions 7012 and the third sub-portion 7013 is smaller than ½ of an area of the gate electrode of the driving transistor.

For example, a sum of areas of the first sub-portion 7011 and the second sub-portions 7012 is smaller than ½ of the area of the gate electrode of the driving transistor.

For example, a sum of the areas of the first sub-portion 7011, the second sub-portions 7012 and the third sub-portion 7013 is smaller than ½ of the area of the gate electrode of the driving transistor.

Based on the above arrangement, it is able to compensate for the voltage at the node N1 within the skip frame more efficiently.

As shown in FIGS. 25 and 30, in some embodiments of the present disclosure, the subpixel driving circuit further includes storage capacitors Cst, second plates Cst2 of the storage capacitors Cst proximate to each other in the first direction are coupled to each other via a conductive member Cst-d, and an orthogonal projection of the first sub-extension member 2022a onto the base substrate at least partially overlaps with an orthogonal projection of the conductive member Cst-d onto the base substrate.

The conductive member Cst-d and the second plate Cst2 are coupled to a power source line in the display substrate, so a power source signal having a stable voltage is transmitted on the conductive member Cst-d. Based on the above arrangement, it is able to prevent crosstalk, improve the stability of the power source signal, and increase the light transmittance of the high-resolution display substrate.

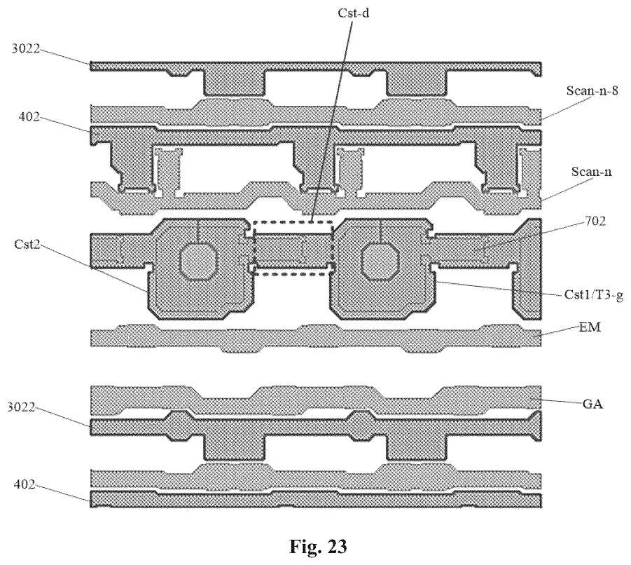

As shown in FIGS. 23, 29 and 30, in some embodiments of the present disclosure, the second auxiliary structure 702 and the gate electrode of the driving transistor form an integral piece, and the orthogonal projection of the second auxiliary structure 702 onto the base substrate at least partially overlaps with an orthogonal projection of the conductive member Cst-d onto the base substrate.

For example, the conductive member Cst-d and the second plate Cst2 of the storage capacitor Cst form an integral piece. The gate electrode of the driving transistor is reused as a first plate Cst1 of the storage capacitor Cst. Based on the above arrangement, it is able to increase a capacitance of the storage capacitor Cst, improve a current leakage at the node N1 at a low frequency, and reduce the occurrence of flicker. In addition, it is able to prevent the occurrence of any interference on the node N1 caused by the other signal in a better manner, thereby to improve image quality.

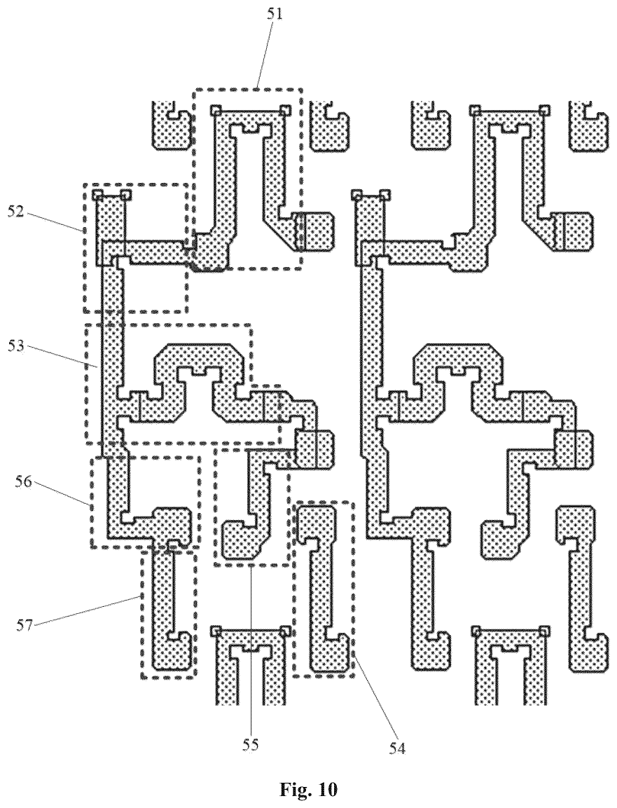

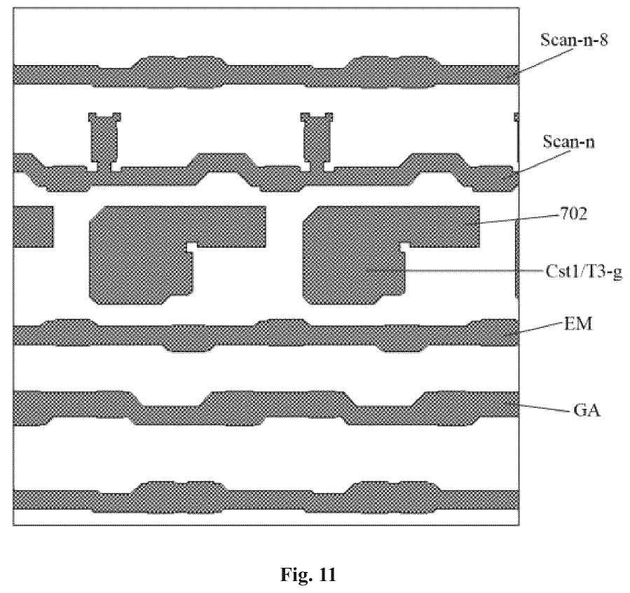

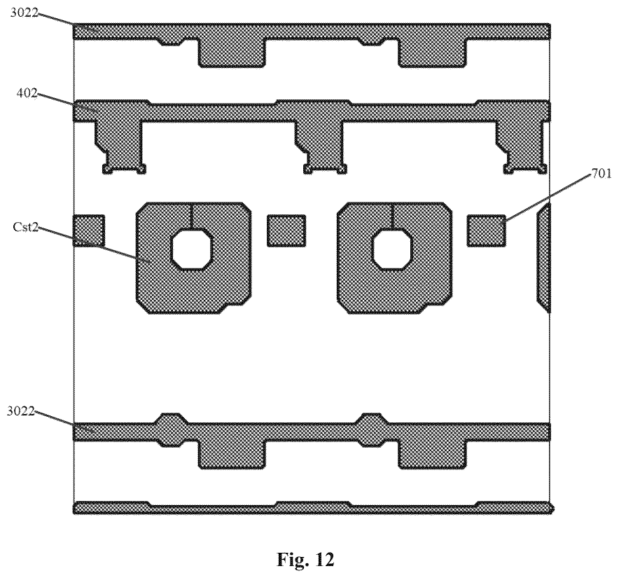

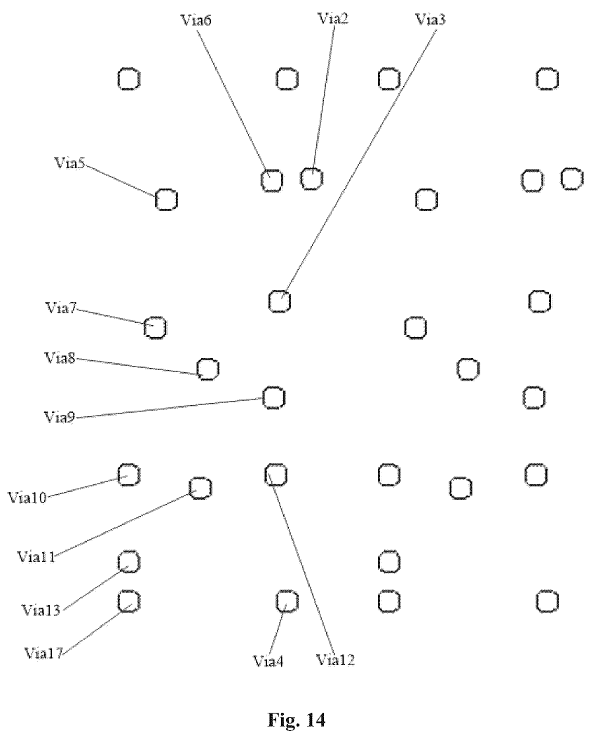

As shown in FIGS. 8 to 14, in some embodiments of the present disclosure, the display substrate further includes a second gate metal layer, the first auxiliary structure 701 is arranged at a same layer, and made of a same material, as the second gate metal layer, and a capacitor structure is formed between the first auxiliary structure 701 and the second auxiliary structure 702.

Based on the above arrangement, the first auxiliary structure 701 and the second auxiliary structure 702 form a parallel-plate capacitor. In a case that a light-emission control signal transmitted via a light-emission control signal is at an inactive level, it is able to change the voltage of the third initialization signal Vinit3. Through adjusting the jump of the third initialization signal Vinit3 within the skip frame, it is able to perform linear compensation on the voltage of the node N1, thereby to compensate for brightness and reduce the occurrence of flicker.

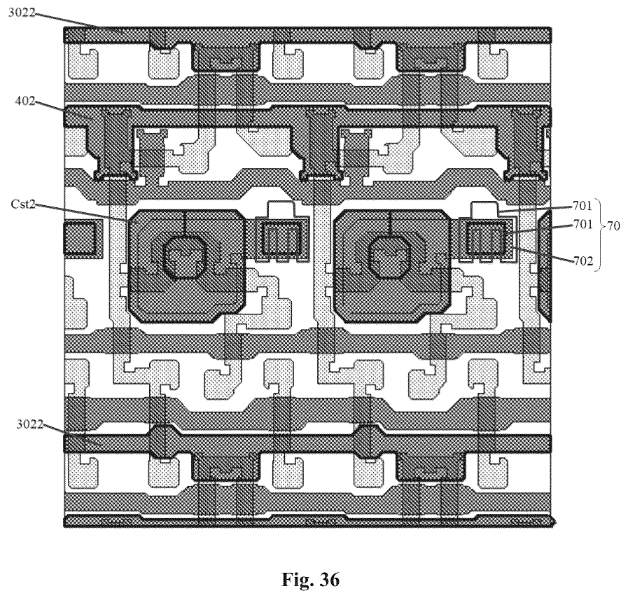

As shown in FIG. 36, in some embodiments of the present disclosure, the auxiliary structure 70 includes two first auxiliary structures 701. One of the two first auxiliary structures 701 is arranged at a same layer, and made of a material, as the active layer, and the other of the two first auxiliary structures 701 is arranged at a same layer, and made of a material, as the second gate metal layer. The first auxiliary structure 701 and the second auxiliary structure 702 form a structure similar to a parallel-plate capacitor.

As shown in FIGS. 8 to 14, in some embodiments of the present disclosure, the orthogonal projection of the second auxiliary structure 702 onto the base substrate completely covers the orthogonal projection of the first auxiliary structure 701 onto the base substrate.

Based on the above arrangement, it is able to improve the process stability, and prepare the capacitor in a precise manner through controlling the single-layered first auxiliary structure 701.

As shown in FIGS. 13, 17 and 32, in some embodiments of the present disclosure, the display substrate further includes a first source/drain metal layer, and the first initialization signal transmission layer 20 is arranged at a same layer, and made of a same material, as the first source/drain metal layer. Based on the above arrangement, it is able to form the first initialization signal transmission layer 20 and the first source/drain metal layer simultaneously through a single patterning processing, thereby to simplify a manufacture process of the display substrate. In addition, it is able to reduce the loading of the first initialization signal transmission layer 20.

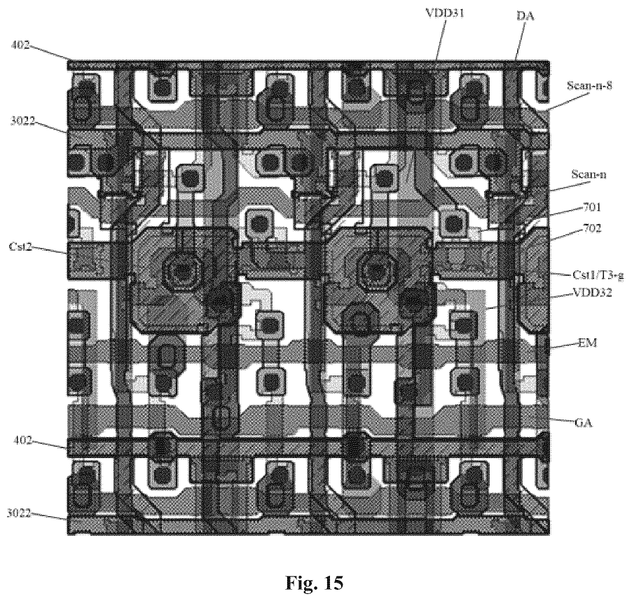

As shown in FIGS. 15 to 34, in some embodiments of the present disclosure, the display substrate further includes a second initialization signal transmission layer including a plurality of second initialization branches 3021 and a plurality of third initialization branches 3022, the plurality of second initialization branches 3021 is arranged in the first direction, the plurality of third initialization branches 3022 is arranged in the second direction, and the third initialization branch 3022 is coupled to the plurality of second initialization branches 3021.

For example, the plurality of subpixel driving circuits in the plurality of subpixels includes a plurality of subpixel driving circuits arranged in the second direction, the subpixel driving circuit row includes a plurality of subpixel driving circuits arranged in the first direction, and the third initialization branch 3022 is coupled to the subpixel driving circuits in a corresponding subpixel driving circuit row.

For example, the second initialization signal transmission layer is configured to transmit, but not limited to, a second initialization signal Vinit2 or a first initialization signal Vinit1.

For example, the second initialization branch 3021 includes at least a portion extending in the second direction, and the third initialization branch 3022 includes at least a portion extending in the first direction.

For example, the quantity of second initialization branches 3021 is smaller than or equal to the quantity of subpixel driving circuit columns.

Based on the above arrangement, the second initialization branch 3021 transmits the initialization signal to the subpixel driving circuit via the third initialization branch 3022, so as to ensure the uniformity of the initialization signals received by the subpixel driving circuits.

Based on the above arrangement, the second initialization signal transmission layer is of a net-like structure, so as to effectively reduce the loading of the second initialization signal transmission layer. In a case that the initialization signal is transmitted to the subpixel driving circuit through the second initialization signal transmission layer, it is able to ensure the uniformity of the initialization signals received by the subpixel driving circuits, thereby to ensure the display uniformity of the display substrate at a low grayscale. In addition, for the display substrate using an under-screen photographing technology, it is able to prevent the occurrence of hole mura.

As shown in FIGS. 15 to 34, in some embodiments of the present disclosure, the display substrate further includes a second gate metal layer and a first source/drain metal layer, the second initialization branch 3021 is arranged at a same layer, and made of a same material, as the first source/drain metal layer, and the third initialization branch 3022 is arranged at a same layer, and made of a same material, as the second gate metal layer.

Based on the above arrangement, the second initialization branch 3021 and the first source/drain metal layer are formed simultaneously through a single patterning process, and the third initialization branch 3022 and the second gate metal layer are formed simultaneously through a single patterning process, so as to simplify the manufacture process of the display substrate.

As shown in FIGS. 15 to 20 and 39, in some embodiments of the present disclosure, the subpixel driving circuit further includes a second resetting transistor, a second electrode of the second resetting transistor is coupled to the gate electrode of the driving transistor, and the third initialization branch 3022 is coupled to a first electrode of the second resetting transistor of the subpixel driving circuit in a corresponding subpixel driving circuit row.

For example, the second initialization signal transmission layer is configured to transmit the first initialization signal Vinit1. The first resetting transistor is configured to reset the gate electrode of the driving transistor by means of the first initialization signal Vinit1.

Based on the above arrangement, the second initialization signal transmission layer includes the plurality of second initialization branches 3021 and the plurality of third initialization branches 3022, and the third initialization branch 3022 is coupled to the first electrode of the first resetting transistor of the subpixel driving circuit in the corresponding subpixel driving circuit row, so as to effectively reduce the loading of the second initialization signal transmission layer. In a case that the initialization signal is transmitted to the subpixel driving circuit by means of the second initialization signal transmission layer, it is able to ensure the uniformity of the first initialization signal Vinit1 received by the subpixel driving circuit.

As shown in FIGS. 15 to 20, in some embodiments of the present disclosure, the second initialization branch 3021 includes a second branch body 3021a and a plurality of second branch extension members 3021b, the second branch body 3021a extends in the second direction, the second branch extension member 3021b protrudes from the second branch body 3021a, the second branch extension member 3021b is coupled to a corresponding third initialization branch 3022, and an orthogonal projection of the second branch extension member 3021b onto the base substrate at least partially overlaps with an orthogonal projection of the third initialization branch 3022 onto the base substrate.

The second branch extension member 3021b and the third initialization branch 3022 transmit a same signal. Based on the above arrangement, the structures for transmitting the same signal overlap with each other, so as to improve the signal stability, reduce a shielding rate, and increase the light transmittance.

As shown in FIGS. 15 to 20, in some embodiments of the present disclosure, the display substrate further includes a third initialization signal transmission layer including a plurality of fourth initialization branches 402, and the fourth initialization branch 402 includes at least a portion extending in the first direction. The subpixel includes a light-emitting element, the subpixel driving circuity further includes a first resetting transistor, a second electrode of the first resetting transistor is coupled to the light-emitting element, and the fourth initialization branch 402 is coupled to a first electrode of the first resetting transistor of the subpixel driving circuit in a corresponding subpixel driving circuit row.

For example, the plurality of fourth initialization branches 402 corresponds to the plurality of subpixel driving circuit rows respectively.

For example, the third initialization signal transmission layer is configured to transmit a second initialization signal Vinit2. The second resetting transistor is configured to reset an anode of the light-emitting element using the second initialization signal Vinit2.

Based on the above arrangement, it is able to effectively reduce the loading of the third initialization signal transmission layer, and ensure the uniformity of the second initialization signal Vinit2 written into the subpixel driving circuit.

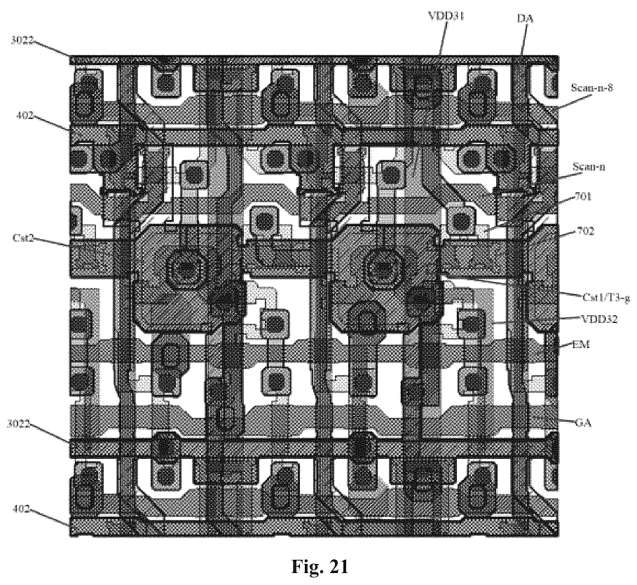

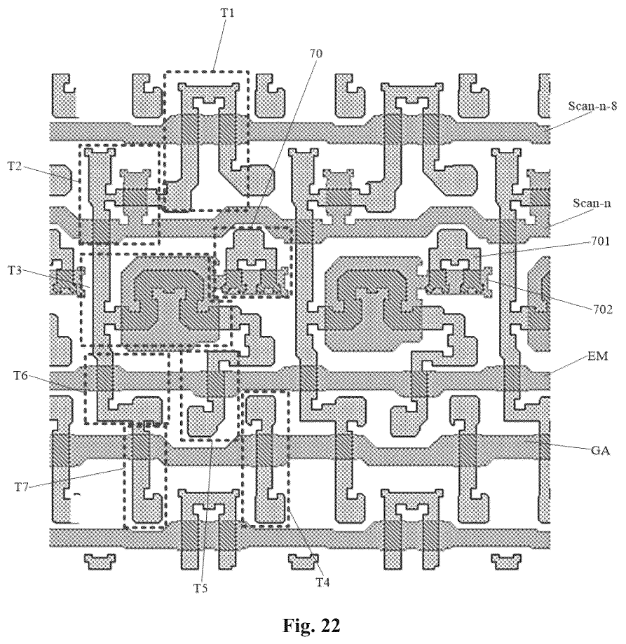

As shown in FIGS. 21 to 34, in some embodiments of the present disclosure, the subpixel includes a light-emitting element, the subpixel driving circuit further includes a second resetting transistor, a second electrode of the second resetting transistor is coupled to the light-emitting element, and the third initialization branch 3022 is coupled to a first electrode of the second resetting transistor in a corresponding subpixel driving circuit.

As shown in FIGS. 21 to 34, in some embodiments of the present disclosure, the plurality of subpixel driving circuits in the plurality of subpixels includes a plurality of subpixel driving circuit rows arranged in the second direction, the subpixel includes a light-emitting element, the subpixel driving circuit further includes a second resetting transistor, a second electrode of the second resetting transistor is coupled to the light-emitting element, and the third initialization branch 3022 is coupled to a first electrode of the second resetting transistor of the subpixel driving circuit in a corresponding subpixel driving circuit row.

For example, the second initialization signal transmission layer transmits the second initialization signal Vinit2.

In the display substrate according to the embodiments of the present disclosure, the second initialization signal transmission layer transmits the second initialization signal Vinit2, and the second resetting transistor resets the anode of the light-emitting element using the signal.

As shown in FIGS. 21 to 34, in some embodiments of the present disclosure, the second initialization branch 3021 includes a second branch body 3021a and a plurality of second branch extension members 3021b, the second branch body 3021a extends in the second direction, the second branch extension member 3021b protrudes from the second branch body 3021a in the first direction, the second branch extension member 3021b is coupled to a corresponding third initialization branch 3022, and an orthogonal projection of the second branch extension member 3021b onto the base substrate at least partially overlaps with an orthogonal projection of the third initialization branch 3022 onto the base substrate.

The second branch extension member 3021b and the third initialization branch 3022 transmit a same signal. Based on the above arrangement, the structures for transmitting the same signal overlap with each other, so as to improve the signal stability, reduce a shielding rate, and increase the light transmittance.

As shown in FIGS. 21 to 34, in some embodiments of the present disclosure, the second branch extension member 3021b includes a third sub-extension member 3021b-1 and a fourth sub-extension member 3021b-2, the third sub-extension member 3021b-1 includes at least a portion extending in the first direction, and the fourth sub-extension member 3021b-2 includes at least a portion extending in the second direction.

An orthogonal projection of the third sub-extension member 3021b-1 onto the base substrate is located within the orthogonal projection of the third initialization branch 3022 onto the base substrate, and a boundary of the orthogonal projection of the third sub-extension member 3021b-1 onto the base substrate at least partially overlaps with a boundary of the orthogonal projection of the third initialization branch 3022 onto the base substrate.

Based on the above arrangement, the orthogonal projection of the third sub-extension member 3021b-1 onto the base substrate at least partially overlaps with the orthogonal projection of the third initialization branch 3022 onto the base substrate, so as to improve the signal stability, reduce a shielding rate, and increase the light transmittance.

As shown in FIGS. 21 to 34, in some embodiments of the present disclosure, the display substrate further includes a third initialization signal transmission layer including a plurality of fourth initialization branches 402, and the fourth initialization branch 402 includes at least a portion extending in the first direction.

The subpixel driving circuity further includes a first resetting transistor, a second electrode of the first resetting transistor is coupled to the gate electrode of the driving transistor, and the fourth initialization branch 402 is coupled to a first electrode of the first resetting transistor of the subpixel driving circuit in a corresponding subpixel driving circuit row.

For example, the plurality of fourth initialization branches 402 correspond to the subpixel driving circuit rows respectively.

For example, the third initialization signal transmission layer is configured to transmit the first initialization signal Vinit1. The first resetting transistor resets the gate electrode of the driving transistor using the first initialization signal Vinit1.

Based on the above arrangement, it is able to effectively reduce the loading of the third initialization signal transmission layer, and ensure the uniformity of the first initialization signal Vinit1 written into the subpixel driving circuit.

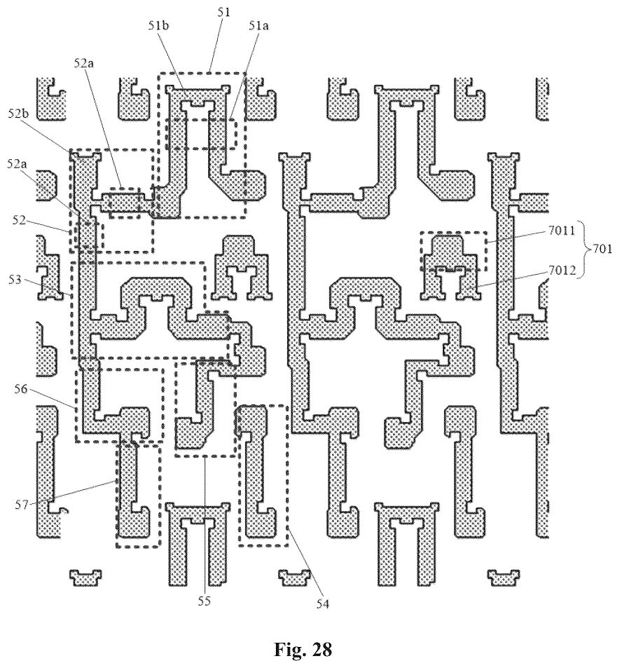

As shown in FIG. 28, in some embodiments of the present disclosure, the first resetting transistor includes a first resetting active layer 51, the first resetting active layer 51 includes two first channel portions 51a and a first conductor portion 51b, and the first conductor portion 51b is coupled to the two first channel portions 51a. As shown in FIG. 25, the orthogonal projection of the third initialization branch 3022 onto the base substrate at least partially overlaps with an orthogonal projection of the first conductor portion 51b onto the base substrate. Alternatively, as shown in FIG. 19, an orthogonal projection of the fourth initialization branch 402 onto the base substrate at least partially overlaps with the orthogonal projection of the first conductor portion 51b onto the base substrate.

For example, the third initialization branch 3022 or the fourth initialization branch 402 transmits the second initialization signal Vinit2 having a stable voltage. The first conductor portion 51b is shielded by the third initialization branch 3022 or the fourth initialization branch 402, so as to achieve a light-shielding effect, thereby to ensure stable characteristics of the first resetting transistor.

As shown in FIG. 28, in some embodiments of the present disclosure, the subpixel driving circuit further includes a compensation transistor, a first electrode of the compensation transistor is coupled to a second electrode of the driving transistor, a second electrode of the compensation transistor is coupled to the gate electrode of the driving transistor, the compensation transistor includes a compensation active layer 52, the compensation active layer 52 includes two compensation channel portions 52a and one compensation conductor portion 52b, and the compensation conductor portion 52b is coupled to the two compensation channel portions 52a.

As shown in FIG. 19, an orthogonal projection of the third initialization branch 3022 onto the base substrate at least partially overlaps with an orthogonal projection of the compensation conductor portion 52b onto the base substrate. Alternatively, as shown in FIG. 25, an orthogonal projection of the fourth initialization branch 402 onto the base substrate at least partially overlaps with the orthogonal projection of the compensation conductor portion 52b onto the base substrate.

It should be appreciated that, the compensation active layer 52 is an active layer of the compensation transistor, and it includes two channel portions and one conductor portion.

For example, the third initialization branch 3022 of the fourth initialization branch 402 transmits the first initialization signal Vinitl having a stable voltage. The compensation conductor portion 52b is shielded by the third initialization branch 3022 or the fourth initialization branch 402, so as to achieve a light-shielding effect, thereby to ensure stable characteristics of the compensation transistor.

In some embodiments of the present disclosure, the second plate Cst2 of the storage capacitor Cst includes an extension member, and an orthogonal projection of the extension member onto the base substrate at least partially overlaps with an orthogonal projection of the compensation conductor portion 52b onto the base substrate. Based on the above arrangement, the compensation conductor portion 52b is shielded, so as to achieve a light-shielding effect, thereby to ensure stable characteristics of the compensation transistor.

In some embodiments of the present disclosure, as shown in FIG. 19, the orthogonal projection of the third initialization branch 3022 onto the base substrate at least overlaps with the orthogonal projection of the second sub-extension member 2022b onto the base substrate; or as shown in FIG. 25, the orthogonal projection of the fourth initialization branch 402 onto the base substrate a least partially overlaps with the orthogonal projection of the second sub-extension member 2022b onto the base substrate.

For example, the third initialization branch 3022 or the fourth initialization branch 402 transmits the first initialization signal Vinit1 having a stable voltage. The third initialization branch 3022 or the fourth initialization branch 402 overlaps with the second sub-extension member 2022b, so as to prevent the occurrence of crosstalk, and increase the light transmittance.

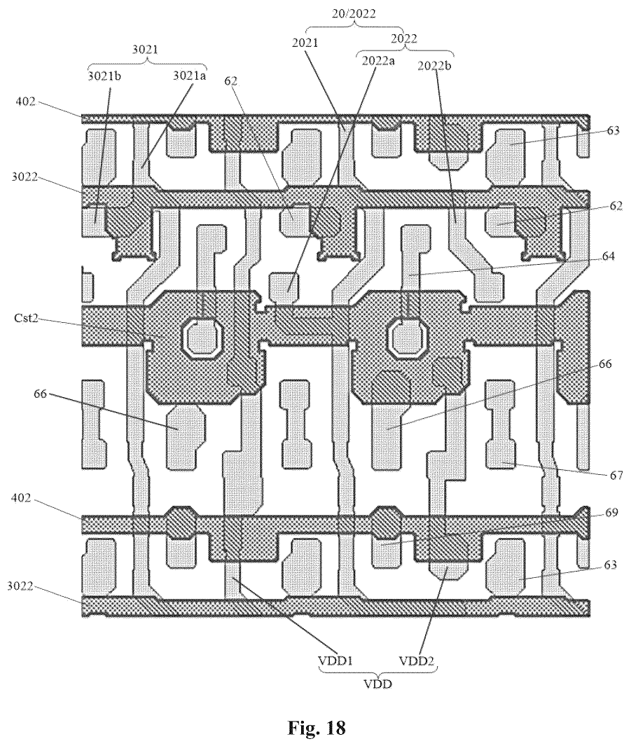

As shown in FIGS. 17, 18, 20, 26 and 34, in some embodiments of the present disclosure, the display substrate further includes a data line DA, and an orthogonal projection of the first branch body 2021 onto the base substrate at least partially overlaps with an orthogonal projection of the data line DA onto the base substrate, and/or an orthogonal projection of the second initialization branch 3021 onto the base substrate at least partially overlaps with the orthogonal projection of the data line DA onto the base substrate.

For example, the display substrate further includes a data line DA, an overlapping area between the orthogonal projection of the first branch body 2021 onto the base substrate and an orthogonal projection of the data line DA onto the base substrate is greater than 80% of an area of the orthogonal projection of the first branch body 2021 onto the base substrate, or an overlapping area between the orthogonal projection of the second initialization branch 3021 onto the base substrate and the orthogonal projection of the data line DA onto the base substrate is greater than 80% of an area of the orthogonal projection of the second initialization branch 3021 onto the base substrate.

Based on the above arrangement, it is able to increase the light transmittance of the display substrate in a better manner.

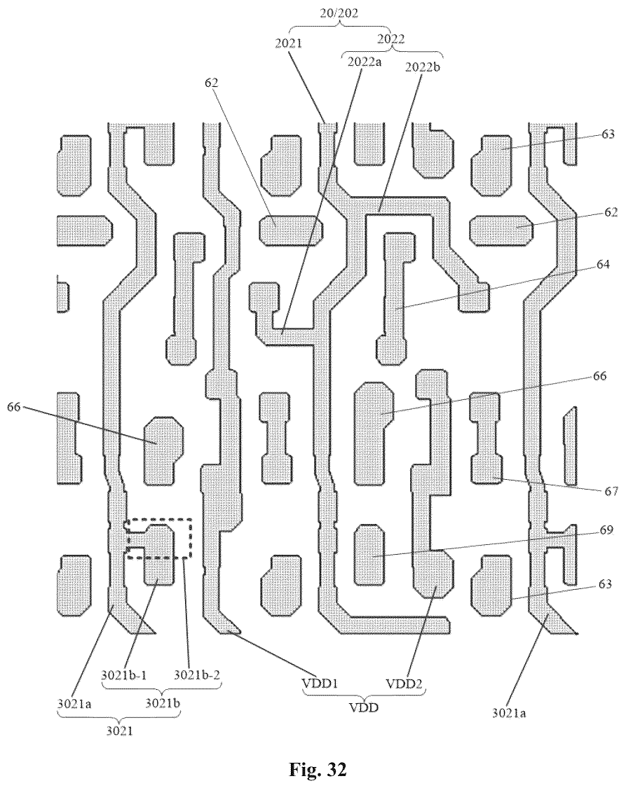

As shown in FIGS. 17 and 32, in some embodiments of the present disclosure, in the first direction, orthogonal projections of a first branch bodies 2021 onto the base substrate and orthogonal projections of b second branch bodies 3021a onto the base substrate are arranged alternately, where a is an integer greater than or equal to 1, and b is an integer greater than or equal to 1.

In some embodiments of the present disclosure, the third initialization signal transmission layer further includes a plurality of fifth initialization branches, the fifth initialization branch includes at least a portion extending in the second direction, and the fifth initialization branch is coupled to the plurality of fourth initialization branches 402.

In the first direction, orthogonal projections of a first branch bodies 2021 onto the base substrate, orthogonal projections of b second branch bodies 3021a onto the base substrate and orthogonal projections of c fifth initialization branches onto the base substrate are arranged alternately, where a is an integer greater than or equal to 1, b is an integer greater than or equal to 1, and c is an integer greater than or equal to 1.

For example, the quantity of first branch bodies 2021 is smaller than the quantity of subpixel driving circuit columns, the quantity of second branch bodies 3021a is smaller than the quantity of subpixel driving circuit columns, and the quantity of fifth initialization branches is smaller than the quantity of subpixel driving circuit columns.

Based on the above arrangement, it is able to reduce the layout difficulty of the first initialization signal transmission layer 20, the second initialization signal transmission layer and the third initialization signal transmission layer while ensuring normal signal transmission.

As shown in FIGS. 17 to 20, 24 to 26, 32 and 34, in some embodiments of the present disclosure, the display substrate further includes a power source layer VDD, the power source layer includes a first power source sub-layer, the first power source sub-layer includes a first power source sub-member VDD1 and a second power source sub-member VDD2 arranged in the first direction, and a length of an orthogonal projection of the first power source sub-member VDD1 onto the base substrate in the second direction is greater than a length of an orthogonal projection of the second power source sub-member VDD2 onto the base substrate in the second direction.

As shown in FIGS. 17 to 20, 24 to 26, 32 and 34, in some embodiments of the present disclosure, the display substrate further includes a power source layer VDD, the power source layer VDD includes a first power source sub-layer, the first power source sub-layer includes a first power source sub-member VDD1 and a second power source sub-member VDD2 arranged in the first direction, and an orthogonal projection of the second power source sub-member VDD2 onto the base substrate does not overlap with an orthogonal projection of the first branch extension member 2022 onto the base substrate.

As shown in FIGS. 17 to 20, 24 to 26, 32 and 34, in some embodiments of the present disclosure, the display substrate further includes a power source layer VDD, the power source layer VDD includes a first power source sub-layer and a second power source sub-layer, and at least a portion of the first power source sub-layer is arranged between the second power source sub-layer and the base substrate.

The first power source sub-layer includes first power source sub-members VDD1 and second power source sub-members VDD2 arranged alternately in the first direction, the first power source sub-member VDD1 is coupled to the subpixel driving circuit in a corresponding subpixel driving circuit column, the second power source sub-member VDD2 includes a plurality of power source patterns arranged in the second direction, and the plurality of power source patterns is coupled to the plurality of subpixel driving circuits in a corresponding subpixel driving circuit column respectively.

The second power source sub-layer includes a plurality of third power source sub-members VDD3 arranged in the first direction, a part of the third power source sub-members VDD3 are coupled to the corresponding first power source sub-member VDD1, and the other part of the third power source sub-members VDD3 are coupled to the plurality of power source patterns of the corresponding second power source sub-member VDD2 respectively.

For example, the first power source sub-layer VDD is arranged at a same layer, and made of a same material, as the first source/drain metal layer, and the second power source sub-layer VDD is arranged at a same layer, and made of a same material, as the second source/drain metal layer.

For example, the first power source sub-member VDD1 is designed in such a manner as to extend longitudinally, the second power source sub-member VDD2 includes a plurality of power source patterns arranged in the second direction and independent of each other, and the power source pattern is merely arranged in a layout region of a corresponding subpixel driving circuit.

For example, the second plates Cst2 of the storage capacitors Cst in the display substrate are coupled to the first power source sub-layer, and the second plates Cst2 in a same row are coupled to each other sequentially in the first direction, so that the power source layer VDD is of a three-layered grid-like structure including the second plate Cst2, the first power source sub-layer and the second power source sub-layer. Through this structure, it is able to reduce the loading of the power source layer VDD, and achieve the uniformity of the display substrate in a display mode with a high brightness and a large current.

For example, the plurality of third power source sub-members VDD3 corresponds to the plurality of subpixel driving circuit columns in the display substrate respectively.

Based on the above arrangement, the second power source sub-member VDD2 includes the plurality of power source patterns arranged in the second direction, so as to prevent the occurrence of a short-circuit between the power source pattern and the second sub-extension member 2022b, thereby to improve the yield of the display device.

As shown in FIGS. 17 to 20, 24 to 26, 32 and 34, in some embodiments of the present disclosure, the power source layer further includes a second power source sub-layer arranged at a side of the first power source sub-layer distal to the base substrate.

The second power source sub-layer includes a plurality of third power source sub-members VDD3 arranged in the first direction, and an orthogonal projection of the third power source sub-member VDD3 onto the base substrate covers the orthogonal projection of the first power source sub-member VDD1 onto the base substrate, and/or the orthogonal projection of the third power source sub-member VDD3 onto the base substrate covers the orthogonal projection of the second power source sub-member VDD2 onto the base substrate.

At least one of the first power source sub-member VDD1 or the second power source sub-member VDD2 is coupled to the third power source sub-member VDD3.

As shown in FIGS. 17 to 20, 24 to 26, 32 and 34, in some embodiments of the present disclosure, the orthogonal projection of the third power source sub-member VDD3 onto the base substrate completely covers the orthogonal projection of the first power source sub-member VDD1 onto the base substrate; and/or the orthogonal projection of the third power source sub-member VDD3 onto the base substrate completely covers the orthogonal projection of the second power source sub-member VDD2 onto the base substrate.

Based on the above arrangement, it is able to improve the signal stability and the light transmittance of the display substrate.

As shown in FIGS. 17 to 20, 24 to 26, 32 and 34, in some embodiments of the present disclosure, at least a portion of the first branch body 2021, at least a portion of the second branch body 3021a and at least a portion of the first power source sub-member VDD1 have a same shape.

For example, a shape of the first branch body 2021 is approximately identical to a shape of the second branch body 3021a.

Based on the above arrangement, it is able to increase the layout uniformity in a layout region where the subpixel driving circuit column is located, thereby to improve the display uniformity of the display substrate in a better manner.

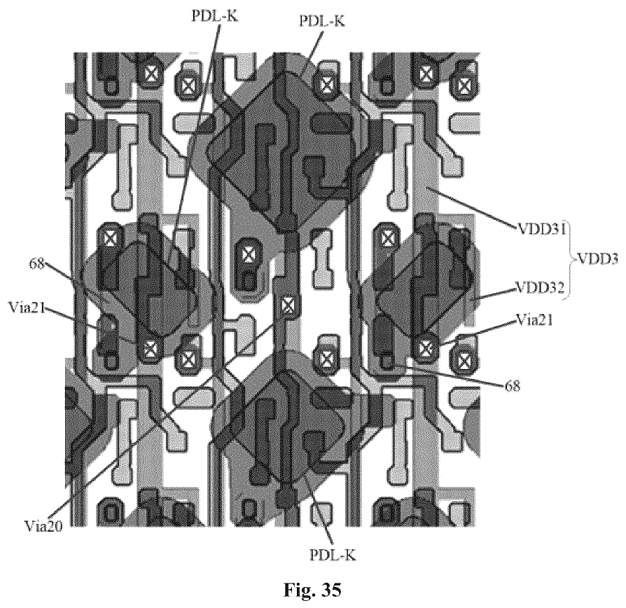

As shown in FIGS. 32 to 35, in some embodiments of the present disclosure, the display substrate further includes a pixel definition layer defining a pixel aperture region PDL-K of the subpixel, the third power source sub-member VDD3 is coupled to a corresponding first power source sub-member VDD1 via a first adaption hole Via20, the third power source sub-member VDD3 is coupled to a corresponding second power source sub-member VDD2 via a second adaption hole Via21, an orthogonal projection of the first adaption hole Via20 onto the base substrate does not overlap with an orthogonal projection of the pixel aperture region PDL-K onto the base substrate, and an orthogonal projection of the second adaption hole Via21 onto the base substrate does not overlap with the orthogonal projection of the pixel aperture region PDL-K onto the base substrate.

For example, the subpixel includes a green subpixel, and the orthogonal projection of the first adaption hole Via20 onto the base substrate is located at a periphery of the orthogonal projection of the pixel aperture region PDL-K of the green subpixel onto the base substrate, or the orthogonal projection of the second adaption hole Via21 onto the base substrate is located at the periphery of the orthogonal projection of the pixel aperture region PDL-K of the green subpixel onto the base substrate.

Based on the above arrangement, it is able to prevent the first adaption hole Via20 and the second adaption hole Via21 from falling within the pixel aperture region PDL-K, thereby to ensure a planarization layer of the anode pattern in the pixel aperture region PDL-K, and ensure the yield of the display substrate.

As shown in FIGS. 32 to 35, in some embodiments of the present disclosure, the third power source sub-member VDD3 includes a power source body VDD31 and a power source extension portion VDD32, the power source body VDD31 includes at least a portion extending in the second direction, and the power source extension portion VDD32 protrudes from the power source body in the first direction.

At least a part of the subpixels include a conductive connection member 68, and the conductive connection member 68 is coupled to the subpixel driving circuit and an anode pattern of a light-emitting element in the subpixel.

An orthogonal projection of the anode pattern in at least a part of the subpixels of the display substrate onto the base substrate at least partially overlaps with an orthogonal projection of the conductive connection member 68 onto the base substrate and at least partially overlaps with an orthogonal projection of the power source extension portion VDD32 onto the base substrate, the conductive connection member 68 is arranged at a same layer, and made of a same material, as the power source extension portion VDD32, and the conductive connection member 68 is arranged opposite to the power source extension portion VDD32 in the first direction.

For example, the conductive connection member 68 and the power source extension portion VDD32 are arranged at a same layer, and made of a same material, as the second source/drain metal layer.

Based on the above arrangement, it is able to ensure the flatness of the anode pattern, thereby to improve the display quality of the display substrate.

In some embodiments of the present disclosure, the display substrate further includes a plurality of first scanning lines GA, the subpixel driving circuit further includes a data write-in transistor and a second resetting transistor, and gate electrodes of the data write-in transistors and gate electrodes of the second resetting transistors in a same subpixel driving circuit row are coupled to a same first scanning line GA.

For example, the plurality of first scanning lines GA corresponds to the plurality of subpixel driving circuit rows respectively, and the first scanning line GA is coupled to the gate electrodes of the data write-in transistors and the gate electrodes of the second resetting transistors in the subpixel driving circuits in a corresponding subpixel driving circuit row.

Based on the above arrangement, the data write-in transistors and the second resetting transistors in a same row are driven using a same shift register unit, so as to reset in principle a same row of subpixels in a same-stage manner, without any necessity to reuse a scanning signal between two adjacent rows. In this way, it is able to achieve the driving in a more flexible, and unlimited, manner, thereby to prevent the reuse of the signal between the adjacent rows due to the insertion of a dummy subpixel driving circuit. It should be appreciated that, in a case that an under-screen photographing technology is used by the display substrate, the display substrate uses a 4+1 subpixel driving circuit layout mode, i.e., a dummy subpixel driving circuit row is provided for every four normal subpixel driving circuit rows. In this layout mode, in a case that a scanning line is reused between a fourth subpixel driving circuit row and a sixth subpixel driving circuit row, the scanning line needs to cross a dummy subpixel driving circuit row, leading to an increase in the layout difficulty of a display panel. Hence, based on the above arrangement, it is unnecessary to reuse the scanning signal between the adjacent rows, so it is able to reduce the layout difficulty.

As shown in FIG. 7, in some embodiments of the present disclosure, the subpixel driving circuit further includes a data write-in transistor (i.e., a fourth transistor T4), and an orthogonal projection of the data write-in transistor onto the base substrate and an orthogonal projection of the auxiliary structure 70 onto the base substrate are arranged at a same side of an orthogonal projection of the gate electrode of the driving transistor (i.e., a third transistor T3) onto the base substrate.

As shown in FIG. 7, in some embodiments of the present disclosure, the subpixel diving circuit further includes a data write-in transistor and a power source control transistor (i.e., a fifth transistor T5), an orthogonal projection of the data write-in transistor onto the base substrate is arranged at a third side of an orthogonal projection of a first electrode of the driving transistor onto the base substrate, an orthogonal projection of the power source control transistor onto the base substrate is arranged at the third side of the orthogonal projection of the first electrode of the driving transistor onto the base substrate, an orthogonal projection of the auxiliary structure 70 onto the base substrate is arranged at a fourth side of the orthogonal projection of the first electrode of the driving transistor onto the base substrate, and the third side is opposite to the fourth side in the second direction.

As shown in FIGS. 22 and 25, in some embodiments of the present disclosure, the subpixel driving circuit further includes a compensation transistor (i.e., a second transistor T2) and a light-emission control transistor (i.e., a sixth transistor T6), an orthogonal projection of a first electrode of the compensation transistor onto the base substrate at least partially overlaps with an orthogonal projection of the first branch body 2021 onto the base substrate, and an orthogonal projection of a first electrode of the light-emission control transistor onto the base substrate at least partially overlaps with the orthogonal projection of the first branch body 2021 onto the base substrate.

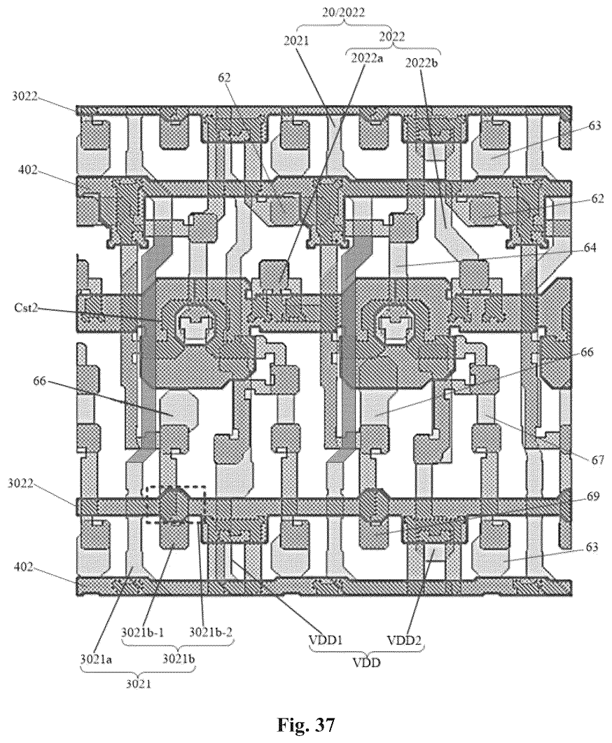

As shown in FIG. 37, in some embodiments of the present disclosure, the subpixel driving circuit further includes a storage capacitor Cst, an orthogonal projection of the first branch body 2021 onto the base substrate at least partially overlaps with an orthogonal projection of a second plate Cst2 of the storage capacitor Cst onto the base substrate, and/or an orthogonal projection of the second initialization branch 3021 onto the base substrate at least partially overlaps with the orthogonal projection of the second plate Cst2 of the storage capacitor Cst onto the base substrate.

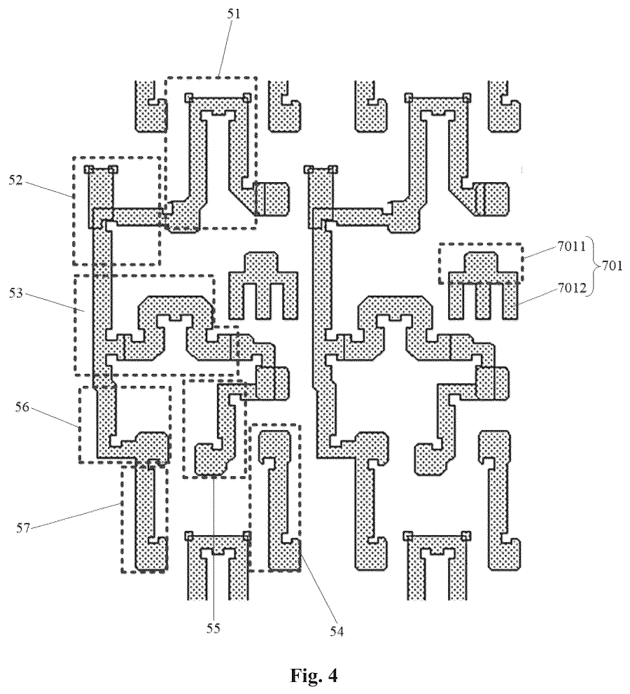

As shown in FIG. 3, in some embodiments of the present disclosure, the display substrate includes a light-shielding layer BSM, an active layer poly, a first gate insulation layer GI1, a first gate metal layer gate1, a second gate metal layer gate2, an interlayer insulation layer ILD, a first source/drain metal layer SD1, a first planarization layer PLN1, a second source/drain metal layer SD2, a second planarization layer PLN2, an anode layer ANO, a pixel definition layer PDL, a light-emitting function layer ELO, a cathode layer cath, a first inorganic encapsulation layer CVD1, an organic encapsulation layer IJP and a second inorganic encapsulation layer CVD2 laminated one on another in a direction away from the base substrate 10. The display substrate further includes, but not limited to, a passivation layer PVX.

As shown in FIG. 1, in some embodiments of the present disclosure, the subpixel driving circuit is of, but not limited to, a 7T1C circuit structure (including 7 transistors and 1 storage capacitor Cst).

The 7T1C circuit structure includes a first transistor T1 (i.e., the first resetting transistor), a second transistor T2 (i.e., the compensation transistor), a third transistor T3 (i.e., the driving transistor), a fourth transistor T4, a fifth transistor T5, a sixth transistor T6, a seventh transistor T7 (i.e., the second resetting transistor) and a storage capacitor Cst. The first transistor T1, the second transistor T2, the third transistor T3, the fourth transistor T4, the fifth transistor T5, the sixth transistor T6 and the seventh transistor T7 are all P-type transistors. In a possible embodiment of the present disclosure, the subpixel driving circuit is a low-temperature poly-silicon pixel driving circuit.

A gate electrode of the first transistor T1 receives a scanning signal from a scanning line Scan-n-8, a first electrode of the first transistor T1 receives the first initialization signal Vinit1, and a second electrode of the first transistor T1 is coupled to a gate electrode T3-g of the third transistor T3.

A gate electrode of the second transistor T2 is coupled to a corresponding scanning line Scan-n, a first electrode of the second transistor T2 is coupled to a second electrode of the third transistor T3, and a second electrode of the second transistor T2 is coupled to the gate electrode T3-g of the third transistor T3. The scanning line Scan-n is a scanning line corresponding to a row where the second transistor T2 is located, and the scanning line Scan-n-8 is a scanning line corresponding to an eighth subpixel driving circuit row before a row where the first transistor T1 is located. The scanning line Scan-n in the eighth subpixel driving circuit row is coupled to the gate electrode of the corresponding second transistor T2. A scanning line coupled to the gate electrode of the first transistor T1 and the scanning line Scan-n-8 share a same shift register unit.

A gate electrode of the fourth transistor T4 is coupled to a corresponding first scanning line GA, a first electrode of the fourth transistor T4 is coupled to a corresponding data line GA, and a second electrode of the fourth transistor T4 is coupled to a first electrode of the third transistor T3.

A gate electrode of the fifth transistor TS is coupled to a corresponding light-emission control signal line EM, a first electrode of the fifth transistor T5 is coupled to a corresponding power source layer VDD, and a second electrode of the fifth transistor TS is coupled to the first electrode of the third transistor T3.

A gate electrode of the sixth transistor T6 is coupled to a corresponding light-emission control signal line EM, a first electrode of the sixth transistor T6 is coupled to the second electrode of the third transistor T3, and a second electrode of the sixth transistor T6 is coupled to an anode of a light-emitting element.

A gate electrode of the seventh transistor T7 is coupled to a corresponding first scanning line GA, a second electrode of the seventh transistor T7 is coupled to the anode of the light-emitting element, and a first electrode of the seventh transistor T7 receives the second initialization signal Vinit2.

A first plate Cst1 of the storage capacitor Cst is coupled to the gate electrode T3-g of the third transistor T3, so the gate electrode of the third transistor T3 is directly reused as the first plate Cst1 of the storage capacitor Cst, and a second plate Cst2 of the storage capacitor Cst is coupled to a corresponding power source layer VDD.

The second capacitor C2 is a parasitic capacitor formed between the first initialization signal transmission layer and the power source layer VDD.

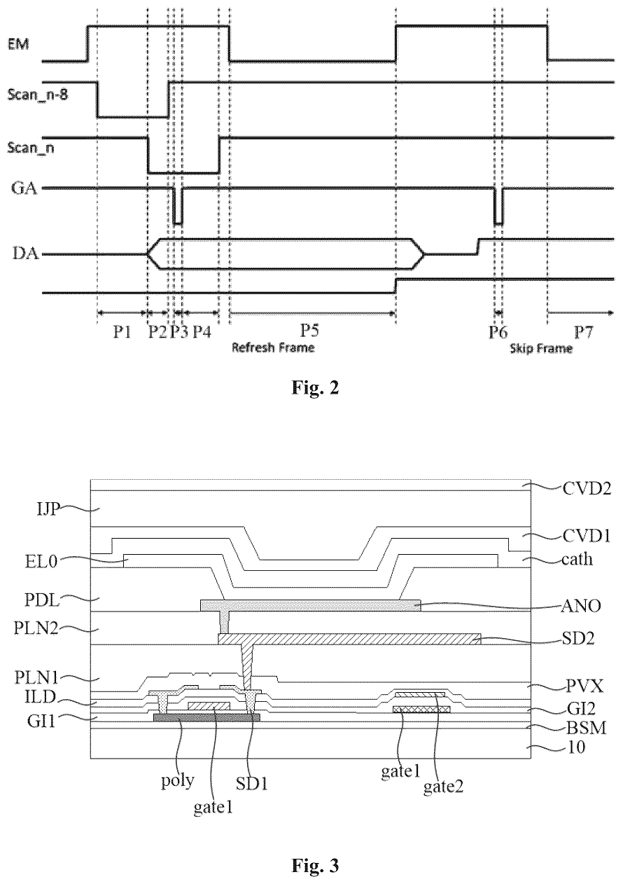

As shown in FIGS. 1 and 2, in a case that a frequency needs to be reduced, there are a refresh frame and a skip frame for an image. Within the refresh frame, all the shift register units (GOA) operate. At a phase P1, the node N1 is reset; at a phase P2, the second electrode of the driving transistor is reset; at a phase P3, a pixel is charged using a data signal; at the end of a phase P4, the scanning line Scan n is disabled; and at a phase P5, the light-emission control signal line EM is enabled continuously. Then, the light-emitting element emits light within the refresh frame.

Within the skip frame, at a phase P6, in a case that the light-emission control signal line EM is disabled (i.e., at a high level), merely the first scanning line GA is enabled (i.e., a first scanning signal from the first scanning line is at a high level), so as to reset and refresh the first anode of the driving transistor and the anode of the light-emitting element. Then, the light-emitting element emits light within the skip frame at a phase P7. In addition, within the skip frame, a voltage of the third initialization signal Vinit3 may change.

As shown in FIGS. 4, 6, 10 and 28, the third transistor T3 includes a third active layer 53, the fourth transistor T4 includes a fourth active layer 54, the fifth transistor T5 includes a fifth active layer 55, the sixth transistor T6 includes a sixth active layer 56, and the seventh transistor T7 includes a seventh active layer 57.

As shown in FIGS. 8 to 14, 15 to 20, and 21 to 34, the first auxiliary structure 701 is coupled to the first sub-extension member 2022a or the second sub-extension member 2022b through a third via-hole Via3.

A second conductive connection member 62 is coupled to the fourth initialization branch 402 or the third initialization branch 3022 through a second via-hole Via2, and the second conductive connection member 62 is coupled to the first electrode of the first transistor TI through a sixth via-hole Via6.

A third conductive connection member 63 is coupled to the first electrode of the fourth transistor T4 through a fourth via-hole Via4, and the third conductive connection member 63 is coupled to the data line D1 through a fifteenth via-hole Via15.

A fourth conductive connection member 64 is coupled to the second electrode of the first transistor T1 through a fifth via-hole Via5, and the fourth conductive connection member 64 is coupled to the gate electrode of the third transistor T3 through a seventh via-hole Via7.

The first power source sub-member VDD1 or the second power source sub-member VDD2 is coupled to the second plate Cst2 of the storage capacitor Cst through an eighth via-hole Via8, the first power source sub-member VDD1 or the second power source sub-member VDD2 is coupled to the third power source sub-member VDD3 through a fourteenth via-hole Via14, and the first power source sub-member VDD1 or the second power source sub-member VDD2 is coupled to the first electrode of the fifth transistor T5 through an eleventh via-hole Viall.

A sixth conductive connection member 66 is coupled to the second electrode of the sixth transistor T6 and the second electrode of the seventh transistor T7 through a tenth via-hole Via10, and the sixth conductive connection member 66 is coupled to an eighth conductive connection member 68 through a seventh via-hole Via7.

A seventh conductive connection member 67 is coupled to the first electrode of the third transistor T3 and the second electrode of the fifth transistor T5 through a ninth via-hole Via9, and the seventh conductive connection member 67 is coupled to the second electrode of the fourth transistor T4 through a twelfth via-hole Via12.

A ninth conductive connection member 69 is coupled to the third initialization branch 3022 or the fourth initialization branch 402 through a thirteenth via-hole Via13, and the ninth conductive connection member 69 is coupled to the first electrode of the seventh transistor T7 through a seventeenth via-hole Via17.

The present disclosure further provides in some embodiments a display device, which includes the above-mentioned display substrate.

It should be appreciated that, the display device may be any product or member having a display function, e.g., television, display, digital photo frame, mobile phone or tablet computer. The display device further includes a flexible circuit board, a printed circuit board and a back plate.

According to the display substrate in the embodiments of the present disclosure, the first auxiliary structure receives the initialization signal via the corresponding first initialization branch. As a result, it is able to not only ensure that the first auxiliary structure in the display substrate receives the initialization signal but also reduce the quantity of first initialization branches, thereby to reduce a layout difficulty of the first initialization signal transmission layer in a limited layout space, and increase the resolution of the display substrate. In addition, the first initialization branch includes the first branch body and the plurality of first branch extension members, and at least one first branch extension member in the plurality of first branch extension members is coupled to the first auxiliary structure in the corresponding subpixel driving circuit. In this way, it is able to effectively reduce a length of the first initialization branch, and reduce a loading of the first initialization branch, thereby to ensure a uniform voltage of the initialization signal received by the subpixel driving circuits at different positions, ensure the display uniformity of a display product in a case of low-grayscale display, and prevent the occurrence of mura.

Furthermore, in the display substrate according to the embodiments of the present disclosure, the auxiliary structure includes the first auxiliary structure and the second auxiliary structure arranged opposite to each other, the first auxiliary structure is coupled to the corresponding first branch extension member, and the second auxiliary structure is coupled to the gate electrode of the driving transistor in the corresponding subpixel driving circuit. In a display process of the display substrate, a voltage of the third initialization signal Vinit3 is adjusted, so as to change an intensity of an electric field between a channel of the driving transistor and the first auxiliary structure, so as to prevent the distribution of defect-state particles at an interface of the channel of the driving transistor from being adversely affected by the electric field, thereby to adjust a hysteresis state of the driving transistor. In addition, the second auxiliary structure is coupled to the gate electrode of the driving transistor, and the second auxiliary structure and the first auxiliary structure form a variable capacitor. In a case of low-frequency writing and within a skip frame, the voltage of the third initialization signal Vinit3 is adjusted, so as to adjust and compensate for a capacitance of a storage capacitor Cst at a node N1 as well as a voltage at the node N1, thereby to reduce an influence of a leakage current Ioff on the voltage at the node N1 in a case of low-frequency display. It is able for the display substrate in the embodiments of the present disclosure to remarkably increase a voltage holding rate of the node NI within one frame at a frequency of 40 Hz, 30 Hz or even 24 Hz, thereby to remarkably improve a flicker effect.

In a case that the display device includes the above display substrate, it also has the above-mentioned beneficial effects, which will not be particularly defined herein.

It should be further appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate clement may be arranged therebetween.

In the above description, the features, structures, materials or characteristics may be combined in any embodiment or embodiments in an appropriate manner.

The above embodiments are for illustrative purposes only, but the present disclosure is not limited thereto. A person skilled in the art may make further alterations and replacements without departing from the spirit of the present disclosure, and these alterations and replacements shall also fall within the scope of the present disclosure. Hence, the scope of the present disclosure shall be subject to the scope of the appended claims.

1. A display substrate, comprising: a base substrate and a plurality of subpixels arranged on the base substrate, wherein each of the subpixels comprises a subpixel driving circuit, a plurality of subpixel driving circuits comprised in the plurality of subpixels comprises a plurality of subpixel driving circuit columns arranged in a first direction, each of the subpixel driving circuit columns comprises a plurality of subpixel driving circuits arranged in a second direction, and the first direction intersects the second direction,
wherein the display substrate further comprises a first initialization signal transmission layer, the first initialization signal transmission layer comprises a plurality of first initialization branches, each of the first initialization branches comprises a first branch body and a plurality of first branch extension members, the first branch body comprises at least a portion extending in the second direction, and each of the first branch extension members comprises at least a portion extending in the first direction;
wherein the subpixel driving circuit comprises a driving transistor and an auxiliary structure, the auxiliary structure comprises a first auxiliary structure and a second auxiliary structure, an orthogonal projection of the first auxiliary structure onto the base substrate at least partially overlaps with an orthogonal projection of the second auxiliary structure onto the base substrate, at least one first branch extension member in the plurality of first branch extension members is coupled to the first auxiliary structure in a corresponding subpixel driving circuit, and the second auxiliary structure is coupled to a gate electrode of the driving transistor of a corresponding subpixel driving circuit.

2. The display substrate according to claim 1, wherein the first branch extension member comprises a first sub-extension member and a second sub-extension member, the first sub-extension member is arranged at a first side of the first branch body, the first sub-extension member is coupled to the first auxiliary structure of a corresponding subpixel driving circuit at the first side of the first branch body, the second sub-extension member is arranged at a second side of the first branch body, the second sub-extension member is coupled to the first auxiliary structure of a corresponding subpixel driving circuit at the second side of the first branch body, and the first side and the second side are different sides of the first branch body.

3. The display substrate according to claim 1, wherein the display substrate comprises an active layer, and the first auxiliary structure is arranged at a same layer, and made of a same material, as the active layer.

4. The display substrate according to claim 1, wherein the first auxiliary structure comprises a first sub-portion and at least two second sub-portions, the at least two second sub-portions are coupled to the first sub-portion, the first sub-portion is coupled to a corresponding first sub-extension member or second sub-extension member, and an orthogonal projection of the second auxiliary structure onto the base substrate at least partially overlaps with an orthogonal projection of the second sub-portion onto the base substrate.

5. The display substrate according to claim 2, wherein the subpixel driving circuit further comprises storage capacitors, second plates of the storage capacitors proximate to each other in the first direction are coupled to each other via a conductive member, and an orthogonal projection of the first sub-extension member onto the base substrate at least partially overlaps with an orthogonal projection of the conductive member onto the base substrate;
wherein the second auxiliary structure and a gate electrode of the driving transistor form an integral piece, and an orthogonal projection of the second auxiliary structure onto the base substrate at least partially overlaps with the orthogonal projection of the conductive member onto the base substrate.

6. (canceled)

7. (canceled)

8. The display substrate according to claim 1, further comprising a first source/drain metal layer, wherein the first initialization signal transmission layer is arranged at a same layer, and made of a same material, as the first source/drain metal layer.

9. The display substrate according to claim 1, further comprising a second initialization signal transmission layer, wherein the second initialization signal transmission layer comprises a plurality of second initialization branches and a plurality of third initialization branches, the plurality of second initialization branches is arranged in the first direction, the plurality of third initialization branches is arranged in the second direction, and the third initialization branch is coupled to the plurality of second initialization branches.

10. The display substrate according to claim 9, further comprising a second gate metal layer and a first source/drain metal layer, wherein the second initialization branch is arranged at a same layer, and made of a same material, as the first source/drain metal layer, and the third initialization branch is arranged at a same layer, and made of a same material, as the second gate metal layer, and/or
wherein the subpixel comprises a light-emitting element, the subpixel driving circuit further comprises a second resetting transistor, a second electrode of the second resetting transistor is coupled to the light-emitting element, and the third initialization branch is coupled to a first electrode of the second resetting transistor comprised in a corresponding subpixel driving circuit.

11. (canceled)

12. (canceled)

13. (canceled)

14. The display substrate according to claim 9, further comprising a third initialization signal transmission layer, wherein the third initialization signal transmission layer comprises a plurality of fourth initialization branches, and each of the fourth initialization branches comprises at least a portion extending in the first direction; and
the subpixel driving circuity further comprises a first resetting transistor, a second electrode of the first resetting transistor is coupled to the gate electrode of the driving transistor, and the fourth initialization branch is coupled to a first electrode of the first resetting transistor of the subpixel driving circuit in a corresponding subpixel driving circuit row,
wherein the first resetting transistor comprises a first resetting active layer, the first resetting active layer comprises two first channel portions and a first conductor portion, the first conductor portion is coupled to the two first channel portions, and the orthogonal projection of the third initialization branch onto the base substrate at least partially overlaps with an orthogonal projection of the first conductor portion onto the base substrate.

15. (canceled)

16. The display substrate according to claim 14, wherein the subpixel driving circuit further comprises a compensation transistor, a first electrode of the compensation transistor is coupled to a second electrode of the driving transistor, a second electrode of the compensation transistor is coupled to the gate electrode of the driving transistor, the compensation transistor comprises a compensation active layer, the compensation active layer comprises two compensation channel portions and one compensation conductor portion, the compensation conductor portion is coupled to the two compensation channel portions, and an orthogonal projection of the fourth initialization branch onto the base substrate at least partially overlaps with an orthogonal projection of the compensation conductor portion onto the base substrate, and/or
wherein an orthogonal projection of the fourth initialization branch onto the base substrate at least partially overlaps with an orthogonal projection of the second sub-extension member onto the base substrate.

17. (canceled)

18. The display substrate according to claim 9, further comprising a data line, wherein an orthogonal projection of the first branch body onto the base substrate at least partially overlaps with an orthogonal projection of the data line onto the base substrate, or an orthogonal projection of the second initialization branch onto the base substrate at least partially overlaps with the orthogonal projection of the data line onto the base substrate.

19. The display substrate according to claim 14, wherein the third initialization signal transmission layer further comprises a plurality of fifth initialization branches, each of the fifth initialization branches comprises at least a portion extending in the second direction, and the fifth initialization branch is coupled to the plurality of fourth initialization branches; and
in the first direction, orthogonal projections of a first branch bodies onto the base substrate, orthogonal projections of b second branch bodies onto the base substrate and orthogonal projections of c fifth initialization branches onto the base substrate are arranged alternately, where a is an integer greater than or equal to 1, b is an integer greater than or equal to 1, and c is an integer greater than or equal to 1.

20. The display substrate according to claim 1, further comprising a power source layer, wherein the power source layer comprises a first power source sub-layer, the first power source sub-layer comprises a first power source sub-member and a second power source sub-member arranged in the first direction, and a length of an orthogonal projection of the first power source sub-member onto the base substrate in the second direction is greater than a length of an orthogonal projection of the second power source sub-member onto the base substrate in the second direction.

21. The display substrate according to claim 1, further comprising a power source layer, wherein the power source layer comprises a first power source sub-layer, the first power source sub-layer comprises a first power source sub-member and a second power source sub-member arranged in the first direction, and an orthogonal projection of the second power source sub-member onto the base substrate does not overlap with an orthogonal projection of the first branch extension member onto the base substrate.

22. The display substrate according to claim 20, wherein the power source layer further comprises a second power source sub-layer arranged at a side of the first power source sub-layer distal to the base substrate;
the second power source sub-layer comprises a plurality of third power source sub-members arranged in the first direction, and an orthogonal projection of the third power source sub-member onto the base substrate covers the orthogonal projection of the first power source sub-member onto the base substrate, and/or the orthogonal projection of the third power source sub-member onto the base substrate covers the orthogonal projection of the second power source sub-member onto the base substrate; and
at least one of the first power source sub-member or the second power source sub-member is coupled to the third power source sub-member.

23. The display substrate according to claim 22, further comprising a pixel definition layer, wherein the pixel definition layer defines a pixel aperture region of the subpixel, the third power source sub-member is coupled to a corresponding first power source sub-member via a first adaption hole, the third power source sub-member is coupled to a corresponding second power source sub-member via a second adaption hole, an orthogonal projection of the first adaption hole onto the base substrate does not overlap with an orthogonal projection of the pixel aperture region onto the base substrate, and an orthogonal projection of the second adaption hole onto the base substrate does not overlap with the orthogonal projection of the pixel aperture region onto the base substrate.

24. The display substrate according to claim 23, wherein the subpixel comprises a green subpixel, and the orthogonal projection of the first adaption hole onto the base substrate is located at a periphery of the orthogonal projection of the pixel aperture region of the green subpixel onto the base substrate, or the orthogonal projection of the second adaption hole onto the base substrate is located at the periphery of the orthogonal projection of the pixel aperture region of the green subpixel onto the base substrate.

25. (canceled)

26. The display substrate according to claim 1, further comprising a plurality of first scanning lines, wherein the subpixel driving circuit further comprises a data write-in transistor and a second resetting transistor, and gate electrodes of the data write-in transistors and gate electrodes of the second resetting transistors in a same subpixel driving circuit row are coupled to a same first scanning line.

27. The display substrate according to claim 1, wherein the subpixel driving circuit further comprises a data write-in transistor, and an orthogonal projection of the data write-in transistor onto the base substrate and an orthogonal projection of the auxiliary structure onto the base substrate are arranged at a same side of an orthogonal projection of the gate electrode of the driving transistor onto the base substrate; and/or
wherein the subpixel diving circuit further comprises a data write-in transistor and a power source control transistor;
an orthogonal projection of the data write-in transistor onto the base substrate is arranged at a third side of an orthogonal projection of a first electrode of the driving transistor onto the base substrate, and an orthogonal projection of the power source control transistor onto the base substrate is arranged at the third side of the orthogonal projection of the first electrode of the driving transistor onto the base substrate; and
an orthogonal projection of the auxiliary structure onto the base substrate is arranged at a fourth side of the orthogonal projection of the first electrode of the driving transistor onto the base substrate, and the third side is opposite to the fourth side in the second direction; and/or
wherein the subpixel driving circuit further comprises a compensation transistor and a light-emission control transistor, an orthogonal projection of a first electrode of the compensation transistor onto the base substrate at least partially overlaps with an orthogonal projection of the first branch body onto the base substrate, and an orthogonal projection of a first electrode of the light-emission control transistor onto the base substrate at least partially overlaps with the orthogonal projection of the first branch body onto the base substrate.

28. (canceled)

29. (canceled)

30. (canceled)

31. A display device, comprising the display substrate according to claim 1.
